(19) United States
(12) Patent Application Publication
(10) Pub. No.: US 2026/0164804 A1
(43) Pub. Date: Jun. 11, 2026

(54) DISPLAY DEVICE

(71) Applicant: LG Display Co., Ltd., Seoul (KR)

(72) Inventors: JeongHyeon CHOI, Paju-si (KR); Youngjun CHOI, Paju-si (KR)

(73) Assignee: LG Display Co., Ltd., Seoul (KR)

(21) Appl. No.: 19/361,576

(22) Filed: Oct. 17, 2025

(30) Foreign Application Priority Data
Dec. 10, 2024 (KR) 10-2024-0183058

(51) Int. Cl. H10D 86/40; G09G 3/3266; H10D 86/60; H10K 59/121; H10K 59/126; H10K 59/131; H10K 102/00

(52) U.S. Cl. CPC H10D 86/471; G09G 3/3266; H10D 86/441; H10D 86/481; H10D 86/60; H10K 59/1213; H10K 59/126; H10K 59/131; H10K 2102/351

(57) ABSTRACT

A display device includes a substrate and a transistor thereon. The transistor includes a drain electrode on the substrate with first and second drain portions, a first spacer on the drain electrode, a source electrode on the first spacer and including first and second source portions, a first active layer extending from an upper surface of the first drain portion to an upper surface of the first source portion along a first side surface of the first spacer, a second active layer extending from an upper surface of the second drain portion to an upper surface of the second source portion along a second side surface of the first spacer, a gate insulation layer on the first and second active layers, and a gate electrode on the gate insulation layer with a first and second gate portions respectively overlapping the first and second active layers.

### CROSS-REFERENCE TO RELATED APPLICATION

This application claims priority from Korean Patent Application No. 10-2024-0183058, filed on Dec. 10, 2024, which is hereby incorporated by reference for all purposes as if fully set forth herein.

### TECHNICAL FIELD

Embodiments of the disclosure relate to a display device.

### DISCUSSION OF THE RELATED ART

As the information society develops, demand for display devices for displaying images is increasing in various forms. Various display devices, such as liquid crystal display devices and organic light emitting display devices, are being utilized in recent years.

A display device may include a display panel having a plurality of subpixels for displaying an image, and a plurality of data lines and a plurality of gate lines for driving the plurality of subpixels, a data driving circuit for outputting data signals to the plurality of data lines, and a gate driving circuit for outputting gate signals to the plurality of gate lines.

Further, a plurality of transistors for different purposes may be disposed on the display panel. Because of the size (area) of the transistors disposed in any area within the display panel, it may be difficult to reduce the size of any area within the display panel. For example, when the gate driving circuit of the gate-in-panel type is disposed on the display panel, it is not easy to reduce the size of the area where the gate driving circuit is disposed on the display panel due to the size of the transistor included in the gate driving circuit.

### SUMMARY

Accordingly, embodiments of the present disclosure are directed to a display device that substantially obviates one or more of the problems due to limitations and disadvantages of the related art.

An aspect of the present disclosure is to provide a display device including a transistor having a structure that may be disposed in a small area.

Another aspect of the present disclosure is to provide a display device including a transistor having excellent performance (e.g., high mobility, excellent output characteristics, etc.), even when it has a structure that may be disposed in a small area.

Another aspect of the present disclosure is to provide a display device including a transistor having a structure capable of reducing the size of the non-display area (e.g., bezel).

Another aspect of the present disclosure is to provide a display device including a transistor having a structure capable of reducing an area where a gate driving circuit is disposed on a display panel.

Another aspect of the present disclosure is to provide a display device having a capacitor configured using an electrode structure of a transistor.

Another aspect of the present disclosure is to provide a display device including transistors having different structures for each area.

Another aspect of the present disclosure is to provide a display device having a structure capable of simultaneously forming transistors having different structures.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a substrate; and a first transistor on the substrate, wherein the first transistor includes: a drain electrode on the substrate and including a first drain portion and a second drain portion, a first spacer on the drain electrode at a portion between the first drain portion and second drain portion, a source electrode on an upper surface of the first spacer, the source electrode including a first source portion and a second source portion, a first active layer extending from an upper surface of the first drain portion to an upper surface of the first source portion along a first side surface of the first spacer, a second active layer extending from an upper surface of the second drain portion to an upper surface of the second source portion along a second side surface of the first spacer, a gate insulation layer on the first active layer and the second active layer, and a gate electrode on the gate insulation layer and including a first gate portion overlapping a first channel area of the first active layer and a second gate portion overlapping a second channel area of the second active layer.

In another aspect, a display device may comprise a substrate; and a first transistor on the substrate, wherein the first transistor includes: a drain electrode on the substrate; an auxiliary source electrode on the substrate and spaced apart from the drain electrode; a first spacer on the drain electrode and on the auxiliary source electrode; a source electrode on an upper surface of the first spacer, the source electrode including a first source portion and a second source portion; a first active layer extending from an upper surface of the drain electrode to an upper surface of the first source portion along a first side surface of the first spacer; a connection electrode along a second side surface of the first spacer and electrically connecting the source electrode on the first spacer to the auxiliary source electrode; a first gate insulation layer on the first active layer; and a gate electrode on the first gate insulation layer and overlapping a first channel area of the first active layer.

According to embodiments of the disclosure, there may be provided a display device including a transistor having a structure that may be disposed in a small area.

According to embodiments of the disclosure, there may be provided a display device including a transistor having excellent performance (e.g., high mobility, excellent output characteristics, etc.), even when it has a structure that may be disposed in a small area.

According to embodiments of the disclosure, there may be provided a display device including a transistor having a structure capable of reducing the size of the non-display area (bezel).

According to embodiments of the disclosure, there may be provided a display device including a transistor having a structure capable of reducing an area where a gate driving circuit is disposed on a display panel.

According to embodiments of the disclosure, there may be provided a display device having a capacitor configured using an electrode structure of a transistor without separately configuring a capacitor required to be connected to the transistor. Thus, the area of the circuit area may be further reduced.

According to embodiments of the disclosure, there may be provided a display device including transistors having different structures for each area.

According to embodiments of the disclosure, there may be provided a display device having a structure capable of simultaneously forming transistors having different structures. Thus, process optimization may be achieved or at least improved.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 illustrates a display device according to embodiments of the disclosure;

FIG. 2 is an equivalent circuit diagram illustrating a subpixel of a display device according to embodiments of the disclosure;

FIG. 3 illustrates a gate driving circuit of a display device according to embodiments of the disclosure;

FIG. 4 illustrates a first transistor including one sub transistor in a display device according to embodiments of the disclosure;

FIG. 5 is a cross-sectional view illustrating a display device according to embodiments of the disclosure;

FIG. 6 illustrates a first transistor including two sub transistors in a display device according to embodiments of the disclosure;

FIG. 7 is a plan view illustrating a first transistor including two sub transistors in a display device according to embodiments of the disclosure;

FIGS. 8 and 9 are cross-sectional views illustrating a first transistor including two sub transistors in a display device according to embodiments of the disclosure;

FIG. 10 illustrates a first transistor including three sub transistors in a display device according to embodiments of the disclosure;

FIG. 11 is a plan view illustrating a first transistor including three sub transistors in a display device according to embodiments of the disclosure;

FIGS. 12 and 13 are cross-sectional views illustrating a first transistor including three sub transistors in a display device according to embodiments of the disclosure;

FIG. 14 illustrates a first transistor including four sub transistors in a display device according to embodiments of the disclosure;

FIG. 15 is a plan view illustrating a first transistor including four sub transistors in a display device according to embodiments of the disclosure;

FIGS. 16 and 17 are cross-sectional views illustrating a first transistor including four sub transistors in a display device according to embodiments of the disclosure;

FIG. 18 illustrates a first transistor including six sub transistors in a display device according to embodiments of the disclosure;

FIG. 19 is a plan view illustrating a first transistor including six sub transistors in a display device according to embodiments of the disclosure; and

FIGS. 20 and 21 are cross-sectional views illustrating a first transistor including six sub transistors in a display device according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to,” “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the disclosure are described in detail with reference to the accompanying drawings.

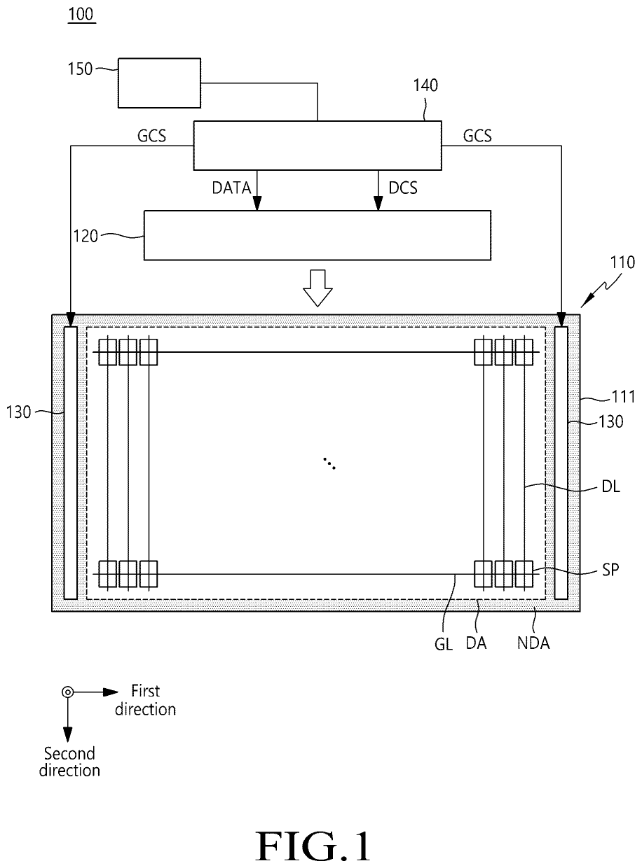

FIG. 1 is a view illustrating a configuration of a display device 100 according to embodiments of the disclosure.

As shown in FIG. 1, a display device 100 according to embodiments of the disclosure may include a display panel 110 and display driving circuits, as components for displaying images. The display driving circuit may be a circuit for driving the display panel 110. The display driving circuits may include a data driving circuit 120, a gate driving circuit 130, and a controller 140, but embodiments of the disclosure are not limited thereto.

The display panel 110 may include a substrate 111 and a plurality of subpixels SP disposed on the substrate 111. The substrate 111 may include a display area DA and a non-display area NDA. The display area DA is an area where images may be displayed, and may also be referred to as an active area. A plurality of subpixels SP for image display may be disposed in the display area DA. The non-display area NDA is an area where no image is displayed and may be an area outside the display area DA. The non-display area NDA may also be referred to as a bezel (or bezel area). The non-display area NDA may include a pad area (pad portion).

The display device 100 according to embodiments of the disclosure may be a self-emission display device in which the display panel 110 emits light by itself, but embodiments of the disclosure are not limited thereto.

For example, the display device 100 may be an organic light emitting diode display in which the light emitting element is implemented as an organic light emitting diode (OLED). As another example, the display device 100 may be an inorganic light emitting display device in which the light emitting element is implemented as an inorganic material-based light emitting diode. As another example, the display device 100 may be a quantum dot display device in which the light emitting element is implemented as a quantum dot which is self-emission semiconductor crystal. As another example, the display device 100 may be a micro LED display device or a mini LED display device.

The structure of each of the plurality of subpixels SP may vary according to the type of the display device 100. For example, when the display panel 110 is a self-luminous display device, each subpixel SP may include a light emitting element that emits light, one or more transistors, and one or more capacitors. However, embodiments of the disclosure are not limited thereto.

Various types of signal lines for driving a plurality of subpixels SP may be disposed on the substrate 111 of the display panel 110. For example, various types of signal lines may include a plurality of data lines DL transferring data signals (also referred to as data voltages or image signals) to a plurality of subpixels SP and a plurality of gate lines GL transferring gate signals (also referred to as scan signals) to the plurality of subpixels SP.

The plurality of data lines DL and the plurality of gate lines GL may cross each other. Each of the plurality of gate lines GL may be disposed to extend in a first direction (e.g., a row direction or column direction). Each of the plurality of data lines DL may be disposed to extend in a second direction (e.g., a column direction or row direction) different from the first direction. For example, the first direction may be the row direction, and the second direction may be the column direction. As another example, the first direction may be the column direction, and the second direction may be the row direction. The row direction and the column direction may be relative directions. For example, the angle between the first direction and the second direction may be 90 degrees or may an angle different from 90 degrees. The data driving circuit 120 may receive digital image data DATA from the controller 140 and may convert the received image data DATA into analog data signals (or also referred to as data voltages) and output them to the plurality of data lines DL.

The gate driving circuit 130 is a circuit for driving the plurality of gate lines GL, and may output gate signals to the plurality of gate lines GL. The gate driving circuit 130 may be embedded in the display panel 110 in a gate-in-panel (GIP) type. In this case, the gate driving circuit 130 may be formed on the substrate 111 of the display panel 110 during the manufacturing process of the display panel 110. When the gate driving circuit 130 is of a gate-in-panel type, the gate driving circuit 130 may be referred to as a gate-in-panel circuit (GIPC).

For example, the gate driving circuit 130 may be disposed in the non-display area NDA of the display panel 110. For example, the gate driving circuit 130 may be disposed in the non-display area NDA on one side or the other side of the display area DA. As another example, gate driving circuits 130 may be disposed in the non-display area NDA on two opposite sides of the display area DA.

As another example, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA). As another example, the gate driving circuit 130 may be disposed over the entire display area DA.

The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material.

For example, the first semiconductor material and the second semiconductor material may be identical. As another example, the first semiconductor material and the second semiconductor material may be different from each other. For example, the first semiconductor material may be a silicon-based semiconductor material (e.g., low temperature poly silicon), and the second semiconductor material may be an oxide semiconductor material. For example, the active layer may be a semiconductor layer. For example, the active layer may be a single layer. As another example, the active layer may be multiple layers.

The controller 140 is a device for controlling the data driving circuit 120 and the gate driving circuit 130, and may supply a data driving control signal DCS to the data driving circuit 120 and may supply a gate driving control signal GCS to the gate driving circuit 130 to control the gate driving circuit 130. The controller 140 may receive input image data from the host system 150 and supply image data DATA to the data driving circuit 120 based on the input image data.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

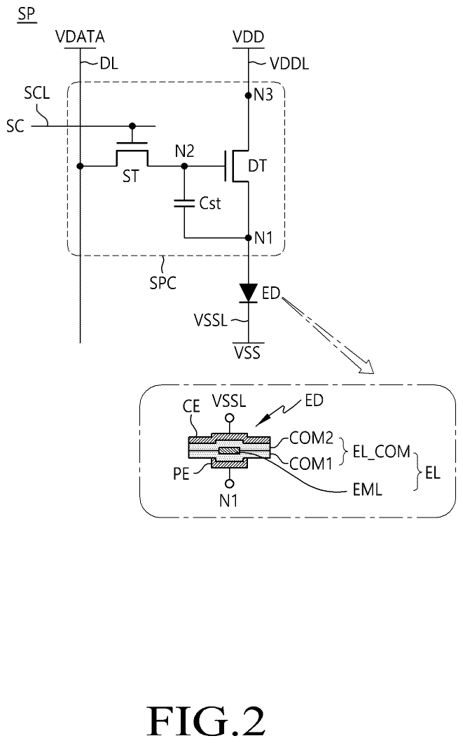

FIG. 2 is an equivalent circuit diagram illustrating a subpixel SP of a display device 100 according to embodiments of the disclosure.

As illustrated in FIG. 2, when the display device 100 is a self-luminous display device, each of the plurality of subpixels SP disposed on the substrate 111 may include a light emitting element ED and a subpixel circuit SPC for driving the light emitting element ED. The subpixel circuit SPC may include a plurality of transistors and at least one capacitor for driving the light emitting element ED. The subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC. The driving transistor DT may supply a driving current to the light emitting element ED. The scan transistor ST may be configured to control the electrical state of a corresponding node in the subpixel circuit SPC or to control the state or operation of the driving transistor DT. The at least one capacitor may include a storage capacitor Cst for maintaining a constant voltage during a frame.

To drive the subpixel SP, a data signal VDATA as an image signal and a scan signal SC which is a kind of gate signal may be applied to the subpixel SP. Further, for driving the subpixel SP, a common driving signal including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

When the light emitting element ED is an organic light emitting element, the intermediate layer EL may include a light emitting layer EML and a common intermediate layer EL_COM. The common layer EL_COM may include a first common intermediate layer COM1 between the pixel electrode PE and the light emitting layer EML, and a second common intermediate layer COM2 between the light emitting layer EML and the common electrode CE. The light emitting layer EML may be disposed for each subpixel SP or may be disposed commonly across a plurality of subpixel SP. The common intermediate layer EL_COM may be disposed commonly across a plurality of subpixel SP. However, embodiments of the disclosure are not limited thereto.

The light emitting layer EML may be disposed for each emission area or disposed commonly across a plurality of emission areas. The common intermediate layer EL_COM may be commonly disposed across a plurality of emission areas and non-emission areas. However, embodiments of the disclosure are not limited thereto.

For example, the first common intermediate layer COM1 may include a hole injection layer HIL, an electron blocking layer EBL, and a hole transport layer HTL, but embodiments of the disclosure are not limited thereto. The second common intermediate layer COM2 may include an electron transport layer ETL, a hole blocking layer HBL, and an electron injection layer EIL, but embodiments of the disclosure are not limited thereto.

For example, the common electrode CE may be electrically connected to the base voltage line VSSL. The base voltage VSS, which is one type of the common voltage, may be applied to the common electrode CE through the base voltage line VSSL. The pixel electrode PE may be electrically connected directly or indirectly (through another transistor) to the first node N1 of the driving transistor DT of each subpixel SP. In the disclosure, “base voltage VSS” may also be referred to as a first common voltage, a low-potential power voltage, or a low-potential voltage, and “base voltage line VSSL” may also be referred to as a first common voltage line, a low-potential power voltage line, or a low-potential voltage line.

Each light emitting element ED may include portions where the pixel electrode PE, the intermediate layer EL, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element ED may be an organic light emitting diode (OLED), an inorganic light emitting diode (LED), a quantum dot light emitting element, a micro LED, or a mini LED, but embodiments of the disclosure are not limited thereto. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node N1, a second node N2, and a third node N3. The first node N1 may be electrically connected to the light emitting element ED, the second node N2 may receive a data signal VDATA, and the third node N3 may receive a driving voltage VDD, which is another kind of common voltage, from the driving voltage line VDDL. The driving transistor DT may be connected between the first node N1 and the third node N3.

In the driving transistor DT, the second node N2 may be a gate node, the first node N1 may be a source node or a drain node, and the third node N3 may be a drain node or a source node. Hereinafter, for convenience of description, an example is described in which in the driving transistor DT, the second node N2 may be a gate node, the first node N1 may be a source node, and the third node N3 may be a drain node, but embodiments of the disclosure are not limited thereto.

The scan transistor ST included in the subpixel circuit SPC illustrated in FIG. 2 may be a switching transistor for transferring the data signal VDATA, which is an image signal, to the second node N2, which is the gate node of the driving transistor DT. The scan transistor ST may be controlled to be turned on and off by the scan signal SC, which is a kind of gate signal applied through the scan line SCL, which is a type of the gate line GL, to control electrical connection between the second node N2 of the driving transistor DT and the data line DL. One of the drain electrode and the source electrode of the scan transistor ST may be electrically connected to the data line DL, the other one of the source electrode and the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and second node N2 of the driving transistor DT. The storage capacitor Cst may include at least one capacitor electrode electrically connected to the first node N1 of the driving transistor DT or corresponding to the first node N1 of the driving transistor DT, and at least one capacitor electrode electrically connected to the second node N2 of the driving transistor DT or corresponding to the second node N2 of the driving transistor DT.

Each of the driving transistor DT and the scan transistor ST may be an n-type transistor or a p-type transistor, but embodiments of the disclosure are not limited thereto. For example, one of the driving transistor DT and the scan transistor ST may be either an n-type transistor or a p-type transistor.

The display panel 110 may have a top emission structure or a bottom emission structure. When the display panel 110 has a top emission structure, at least a portion of the subpixel circuit SPC may overlap at least a portion of the light emitting element ED in a vertical direction. Accordingly, the area of the emission area may increase and the aperture ratio may increase. When the display panel 110 has a bottom emission structure, the subpixel circuit SPC may not overlap the light emitting element ED in the vertical direction.

As illustrated in FIG. 2, the subpixel circuit SPC may have a 2 T (Transistor) 1 C (Capacitor) structure including two transistors DT and ST and one capacitor Cst. In some cases, the subpixel circuit SPC may further include one or more transistors or may further include one or more capacitors.

Because the circuit elements (e.g., the light emitting element ED implemented as an organic light emitting diode (OLED) including an organic material) in each subpixel SP are vulnerable to external moisture or oxygen, the encapsulation layer may be disposed on the display panel 110. The encapsulation layer may prevent, or at least reduce, external moisture or oxygen from penetrating into circuit elements (e.g., the light emitting element ED). The encapsulation layer may be configured in various forms so that the light emitting elements ED do not contact moisture or oxygen.

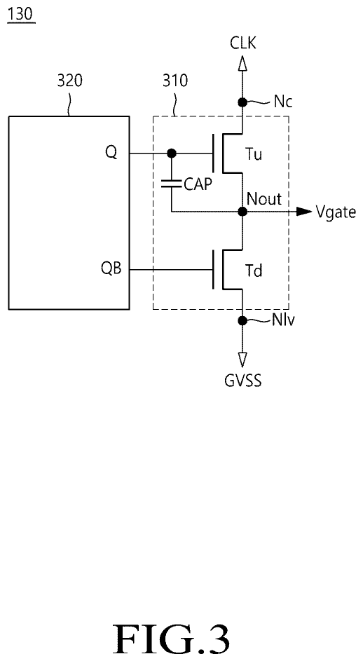

FIG. 3 illustrates a gate driving circuit 130 of a display device according to embodiments of the disclosure.

The gate driving circuit 130 according to embodiments of the disclosure may further include an output buffer circuit 310 for outputting a gate signal Vgate and a control circuit 320 for controlling the output buffer circuit 310. The output buffer circuit 310 may receive a clock signal CLK and a low-potential gate voltage GVSS, and output a gate signal Vgate to the output node Nout.

The output node Nout may be electrically connected to the gate line GL. For example, the output node Nout may be electrically connected to the scan line SCL. In this case, the gate signal Vgate output to the output node Nout may be a scan signal SC.

The output buffer circuit 310 may include a pull-up transistor Tu and a pull-down transistor Td, and may output a gate signal Vgate to the output node Nout to which the pull-up transistor Tu and the pull-down transistor Td are connected. The pull-up transistor Tu may switch the connection between the clock node Nc and the output node Nout according to the voltage of the Q node, and the pull-down transistor Td may switch the connection between the low-potential voltage node Nlv and the output node Nout according to the voltage of the QB node.

The Q node and QB node may have different voltage states. For example, if the Q node has a high level voltage, the QB node may have a low level voltage. If the Q node has a low level voltage, the QB node may have a high level voltage. If the Q node has a high level voltage, the pull-up transistor Tu may be turned on and may output a gate signal Vgate having a high level voltage in the clock signal CLK. In this case, the QB node has a low level voltage, and accordingly, the pull-down transistor Td may be turned off.

If the QB node has a high level voltage, the pull-down transistor Td is turned on and may output a gate signal Vgate having a low level voltage of the low-potential gate voltage GVSS. In this case, the Q node has a low level voltage, and accordingly, the pull-up transistor Tu may be turned off.

In the pull-up transistor Tu, a capacitor CAP may be electrically connected between the Q node, which is the gate node, and the output node Nout. The capacitor CAP may boost the voltage of the Q node according to the voltage variation of the output node Nout.

The control circuit 320 may control the voltage of the Q node electrically connected to the gate node of the pull-up transistor Tu and control the voltage of the QB node electrically connected to the gate node of the pull-down transistor Td. The QB node may receive a DC voltage or an AC signal through at least one transistor.

The control circuit 320 may include a plurality of transistors to control the respective voltages of the Q node and the QB node. For example, the control circuit 700 may include one or more transistors for charging the Q node, one or more transistors for discharging the Q node, one or more transistors for charging the QB node, and one or more transistors for discharging the QB node. The control circuit 320 may receive a start signal, a reset signal, and the like to control the respective voltages of the Q node and the QB node and may further receive a carry signal according to the gate driving scheme.

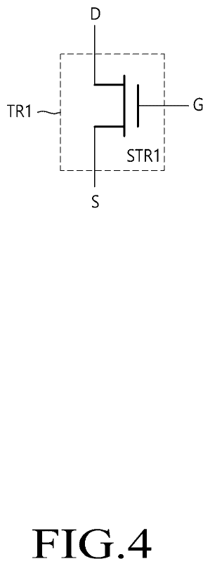

Hereinafter, the structure of a transistor included in a display device 100 according to embodiments of the disclosure is described with reference to FIGS. 4 to 21. In the following description, a reference may also be made to FIGS. 1 to 3.

FIG. 4 illustrates a first transistor TR1 including one sub transistor STR1 in a display device 100 according to embodiments of the disclosure.

The first transistor TR1 included in the display device 100 may include a first sub transistor STR1. The first sub transistor STR1 may include a drain node D, a source node S, and a gate node G.

For example, the first transistor TR1 may be a vertical transistor. For example, the first transistor TR1 may be disposed in the non-display area NDA. For example, the first transistor TR1 may be a transistor included in the gate driving circuit 130. At least one of the transistors included in the gate driving circuit 130 may be the first transistor TR1. For example, at least one of the pull-up transistor Tu and the pull-down transistor Td included in the gate driving circuit 130 may be the first transistor TR1.

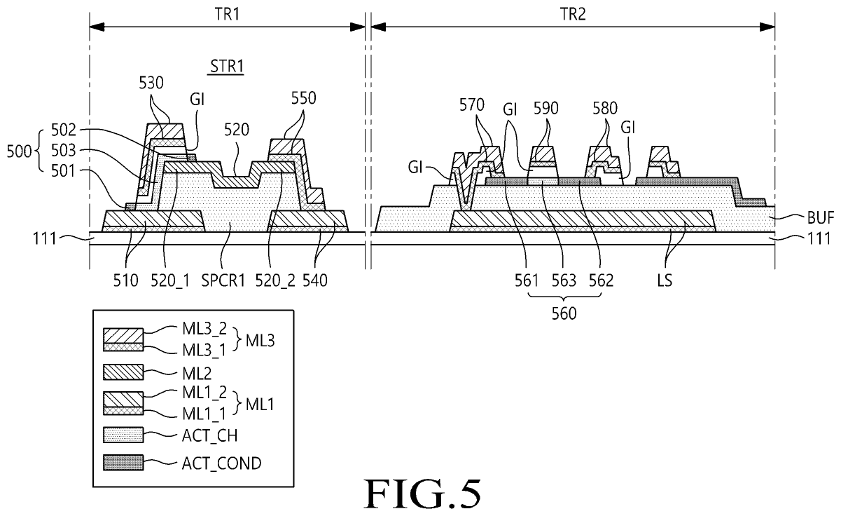

FIG. 5 is a cross-sectional view illustrating a display device 100 according to embodiments of the disclosure.

The display device 100 may include a substrate 111 and a first transistor TR1 disposed on the substrate 111, and the first transistor TR1 may include a first active layer 500, a drain electrode 510, a source electrode 520, a gate electrode 530, a first spacer SPCR1, and a gate insulation layer GI. The drain electrode 510 may be an electrode corresponding to the drain node D, and may be disposed on the substrate 111. The first spacer SPCR1 may be disposed on the drain electrode 510. For example, the first spacer SPCR1 may be disposed on a portion of the drain electrode 510. The source electrode 520 is an electrode corresponding to the source node S, is disposed on the first spacer SPCR1, and may include a first source portion 520_1 and a second source portion 520_2.

The first active layer 500 may include a first channel area 503, a first drain connection area 501 positioned on one side of the first channel area 503, and a first source connection area 502 positioned on the other side of the first channel area 503. For example, the first channel area 503 may include a semiconductor material ACT_CH forming a channel, and the first drain connection area 501 and the first source connection area 502 may include a conductive semiconductor material ACT_COND. The first active layer 500 may extend from the upper surface of the drain electrode 510 to the upper surface of the first source portion 520_1 along the first side surface of the first spacer SPCR1.

The first drain connection area 501 may be connected to the upper surface of the drain electrode 510, and the first source connection area 502 may be connected to the first source portion 520_1 of the source electrode 520. The first channel area 503 may connect the first drain connection area 501 and the first source connection area 502, and may be disposed on a first side surface of the first spacer SPCR1.

The gate insulation layer GI may be disposed on the first active layer 500. For example, the gate insulation layer GI may be disposed on the first channel area 503. The gate electrode 530 is an electrode corresponding to the gate node G, is disposed on the gate insulation layer GI, and may overlap the first channel area 503 of the first active layer 500.

The first transistor TR1 may further include an auxiliary source electrode 540 and a connection electrode 550. The auxiliary source electrode 540 is disposed on the substrate 111 and may be spaced apart from the drain electrode 510. The first spacer SPCR1 may be disposed on the drain electrode 510 and the auxiliary source electrode 540. For example, the first spacer SPCR1 may be disposed on a portion of the drain electrode 510 and a portion of the auxiliary source electrode 540.

The connection electrode 550 may be disposed along the second side surface of the first spacer SPCR1, and may electrically connect the source electrode 520 on the first spacer SPCR1 to the auxiliary source electrode 540.

The first transistor TR1 may further include the auxiliary source electrode 540 and the connection electrode 550 to reduce the electrical resistance of the source node S of the first transistor TR1, thereby increasing the electrical stability of the source node S of the first transistor TR1. As a result, output characteristics of the first transistor TR1 may be enhanced.

As shown in FIG. 5, the display device 100 may further include a second transistor TR2 disposed on the substrate 111. The second transistor TR2 may include an active layer 560, a first electrode 570, a second electrode 580, a third electrode 590, and a gate insulation layer GI.

The active layer 560 is disposed on the substrate 111, and may include a channel area 563, a first connection area 561 positioned on one side of the channel area 563, and a second connection area 562 positioned on the other side of the channel area 563.

The first electrode 570 may be connected to the first connection area 561. The second electrode 580 may be connected to the second connection area 562. The gate insulation layer GI may be disposed on the channel area 563. The third electrode 590 is disposed on the gate insulation layer GI and may overlap the channel area 563.

For example, the gate insulation layer GI may be formed in an etch structure. In this case, as shown in FIG. 5, the gate insulation layer GI may not be disposed between the first electrode 570 and the third electrode 590, and may not be disposed between the second electrode 580 and the third electrode 590. As another example, the gate insulation layer GI may be formed in an etch-less structure. In this case, the gate insulation layer GI may be disposed between the first electrode 570 and the third electrode 590, and may be disposed between the second electrode 580 and the third electrode 590.

As illustrated in FIG. 5, the display device 100 may further include a buffer layer BUF disposed between the substrate 111 and the second transistor TR2, and a shield pattern LS disposed between the substrate 111 and the buffer layer BUF and overlapping at least a portion of the second transistor TR2. For example, the shield pattern LS may overlap the active layer 560 of the second transistor TR2. The first electrode 570 may be electrically connected to the shield pattern LS through a hole of the buffer layer BUF. The first electrode 570 may be electrically connected to the shield pattern LS through holes of the gate insulation layer GI and the buffer layer BUF.

The first spacer SPCR1 may include the same insulating material as the buffer layer BUF. However, the first spacer SPCR1 may have a thickness larger than that of the buffer layer BUF.

The first spacer SPCR1 and the buffer layer BUF may be simultaneously formed through a multi-tone process. Therefore, the first spacer SPCR1 and the buffer layer BUF may include the same insulating material.

By performing differential etching on the buffer layer BUF, a first spacer SPCR1 thicker than the buffer layer BUF may be formed together with the buffer layer BUF. Accordingly, the thickness of the first spacer SPCR1 may be controlled. By controlling the thickness of the first spacer SPCR1, the length (channel length) of the first channel area 503 of the first transistor TR1 may be adjusted to a desired value.

The shield pattern LS may be disposed in the first metal layer ML1. The drain electrode 510 and the auxiliary source electrode 540 of the first transistor TR1 may be disposed in the first metal layer ML1 together with the shield pattern LS.

The source electrode 520 of the first transistor TR1 may be disposed in the second metal layer ML2. The gate electrode 530 and the connection electrode 550 of the first transistor TR1 may be disposed in the third metal layer ML3.

The first electrode 570, the second electrode 580, and the third electrode 590 of the second transistor TR2 may be disposed in the third metal layer ML3. Therefore, the source electrode 520 of the first transistor TR1 may be disposed in the second metal layer ML2 different from the third metal layer ML3 in which the first electrode 570, the second electrode 580, and the third electrode 590 of the second transistor TR2 are disposed.

The gate electrode 530 of the first transistor TR1 may be disposed in the third metal layer ML3 that is the same as at least one of the first electrode 570, the second electrode 580, and the third electrode 590. For example, the gate electrode 530 of the first transistor TR1 may be disposed together in the third metal layer ML3 in which the first electrode 570, the second electrode 580, and the third electrode 590 are disposed.

The second metal layer ML2 may be a metal layer between the first metal layer ML1 and the third metal layer ML3. The second metal layer ML2 may be a metal layer used when the first transistor TR1 is formed, and may be a metal layer not used when the second transistor TR2 is formed.

For example, the first metal layer ML1 may be a single metal layer. As another example, the first metal layer ML1 may be a multi-metal layer. For example, the first metal layer ML1 may be a double metal layer including a first lower metal layer ML1_1 and a second upper metal layer ML1_2. The first lower metal layer ML1_1 and the second upper metal layer ML1_2 may be electrically connected to each other. For example, the first lower metal layer ML1_1 may include copper (Cu) or the like, and the second upper metal layer ML1_2 may include molybdenum titanium (MoTi) or the like. However, the disclosure is not limited thereto, and the first lower metal layer ML1_1 and the second upper metal layer ML1_2 may be formed of various metals or alloys.

For example, the second metal layer ML2 may be a single metal layer. As another example, the second metal layer ML2 may be a multi-metal layer.

For example, the third metal layer ML3 may be a single metal layer. As another example, the third metal layer ML3 may be a multi-metal layer. For example, the third metal layer ML3 may be a double metal layer including a third lower metal layer ML3_1 and a third upper metal layer ML3_2. The third lower metal layer ML3_1 and the third upper metal layer ML3_2 may be electrically connected to each other. For example, the third lower metal layer ML3_1 may include copper (Cu) or the like, and the third upper metal layer ML3_2 may include molybdenum titanium (MoTi) or the like. However, the disclosure is not limited thereto, and the third lower metal layer ML3_1 and the third upper metal layer ML3_2 may be formed of various metals or alloys.

Hereinafter, for convenience of description, an example where the first metal layer ML1 and the third metal layer ML3 are double metal layers and the second metal layer ML2 is a single metal layer is described. However, embodiments of the disclosure are not limited thereto.

Meanwhile, the display panel 110 according to embodiments of the disclosure may further include a gate line GL disposed on the substrate 111, a sub-pixel SP disposed on the substrate 111 and connected to the gate line GL, and a gate driving circuit 130 disposed on the substrate 111 and outputting a gate signal Vgate having a turn-on level voltage or a turn-off level voltage to the gate line GL.

For example, the first transistor TR1 may be a transistor included in the gate driving circuit 130. At least one of the transistors included in the gate driving circuit 130 may be the first transistor TR1. For example, at least one of the pull-up transistor Tu and the pull-down transistor Td included in the output buffer circuit 310 of the gate driving circuit 130 may be the first transistor TR1. For example, the source electrode 520 or the drain electrode 510 of the first transistor TR1 may correspond to the output node Nout and may be electrically connected to the gate line GL.

Since the pull-up transistor Tu and the pull-down transistor Td included in the output buffer circuit 310 require high performance (e.g., high mobility such as a high carrier mobility of electrons or holes), a large channel width may be required. Accordingly, typically, the pull-up transistor Tu and the pull-down transistor Td included in the output buffer circuit 310 may be designed with a large area.

For example, the second transistor TR2 may be included in the sub pixel SP. For example, the second transistor TR2 may be a driving transistor DT included in the sub pixel SP. As another example, the second transistor TR2 may be a scan transistor ST included in the sub pixel SP. In this case, the second transistor TR2, which is the scan transistor ST, may be turned on or off by the gate signal Vgate output from the first transistor TR1.

The first transistor TR1 may have an area (e.g., in a plan view) smaller than the area of the second transistor TR2, or may have a mobility larger than the mobility of the second transistor TR2.

The first transistor TR1 may have an area (e.g., in a plan view) smaller than that of the second transistor TR2. Therefore, the area of the gate-in-panel (GIP) type gate driving circuit 130 including the first transistor TR1 may be significantly reduced. Accordingly, the size of the non-display area NDA of the display panel 110 may be greatly reduced.

The first transistor TR1 may be a vertical transistor, and the second transistor TR2 may be a coplanar transistor. The first transistor TR1 may have higher mobility and better output characteristics than the second transistor TR2.

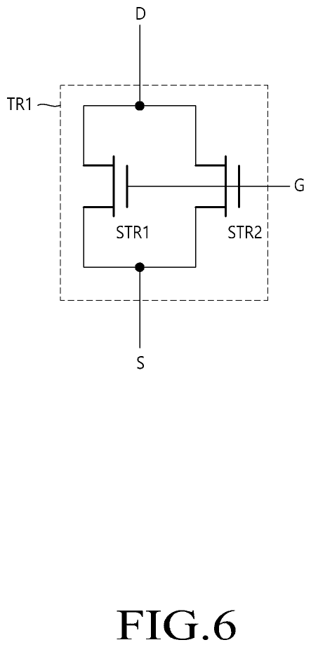

Hereinafter, a case in which the first transistor TR1 includes a plurality of sub transistors is described. First, the first transistor TR1 including two sub transistors is described with reference to FIGS. 6 to 9.

FIG. 6 illustrates a first transistor TR1 including two sub transistors STR1 and STR2 in a display device 100 according to embodiments of the disclosure.

In accordance with FIG. 6, the first transistor TR1 may include a first sub transistor STR1 and a second sub transistor STR2. The first sub transistor STR1 and the second sub transistor STR2 may be connected in parallel. The drain node D of each of the first sub transistor STR1 and the second sub transistor STR2 may be electrically connected, the respective source nodes S of the first sub transistor STR1 and the second sub transistor STR2 may be electrically connected, and the respective gate nodes G of the first sub transistor STR1 and the second sub transistor STR2 may be electrically connected.

The first sub transistor STR1 and the second sub transistor STR2 may be simultaneously turned on or off. For example, each of the first sub transistor STR1 and the second sub transistor STR2 may be a vertical transistor. For example, the first transistor TR1 may be disposed in the non-display area NDA. For example, the first transistor TR1 may be a transistor included in the gate driving circuit 130. At least one of the transistors included in the gate driving circuit 130 may be the first transistor TR1. For example, at least one of the pull-up transistor Tu and the pull-down transistor Td included in the gate driving circuit 130 may be the first transistor TR1.

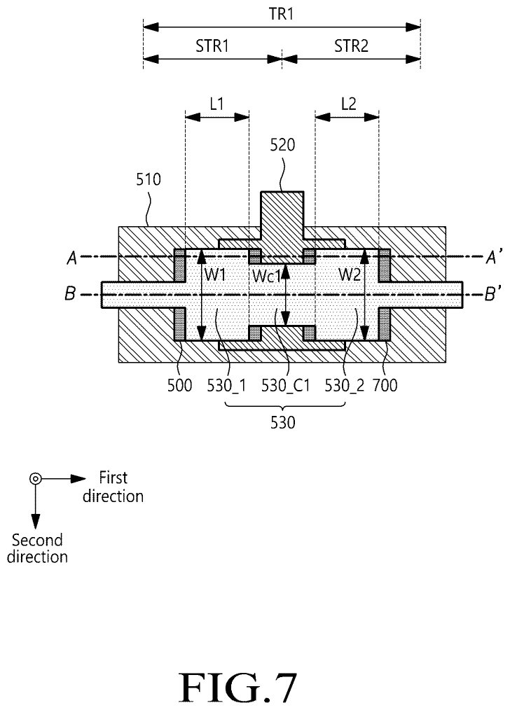

Hereinafter, a planar structure and a vertical structure of the first transistor TR1 of FIG. 6 are described with reference to FIGS. 7 to 9.

FIG. 7 is a plan view illustrating a first transistor TR1 including two sub transistors STR1 and STR2 in a display device 100 according to embodiments of the disclosure.

The first transistor TR1 may include a drain electrode 510 corresponding to the drain node D, a source electrode 520 corresponding to the source node S, a gate electrode 530 corresponding to the gate node G, and may further include a first active layer 500 and a second active layer 700.

Among the drain electrode 510, the source electrode 520, and the gate electrode 530, the drain electrode 510 may be widely disposed at the lowermost side. The source electrode 520 may be disposed on the drain electrode 510, and may overlap the drain electrode 510 in a vertical direction. The gate electrode 530 may be disposed on the drain electrode 510, and may overlap the drain electrode 510 in a vertical direction. The first active layer 500 and the second active layer 700 may be disposed to be spaced apart from each other in a first direction (e.g., a row direction).

The gate electrode 530 may include a first gate portion 530_1 overlapping a portion (e.g., a first channel area) of the first active layer 500, a second gate portion 530_2 overlapping a portion (e.g., a second channel area) of the second active layer 700, and a first connection portion 530_C1 connecting the first gate portion 530_1 and the second gate portion 530_2.

For example, the first gate portion 530_1, the first connection portion 530_C1, and the second gate portion 530_2 may be arranged in the first direction (e.g., the row direction).

An area in which the first active layer 500 and the first gate portion 530_1 are disposed may correspond to an area of the first sub transistor STR1, and an area in which the second active layer 700 and the second gate portion 530_2 are disposed may correspond to an area of the second sub transistor STR2.

The first width W1 of the first gate portion 530_1 in the second direction may be larger than the first connection width Wc1 of the first connection portion 530_C1 in the second direction (W1>Wc1). The second width W2 of the second gate portion 530_2 in the second direction may be larger than the first connection width Wc1 of the first connection portion 530_C1 in the second direction (W2>Wc1).

The first width W1 of the first gate portion 530_1 in the second direction may correspond to the first channel width of the first active layer 500 of the first sub transistor STR1, and the second width W2 of the second gate portion 530_2 in the second direction may correspond to the second channel width of the second active layer 700 of the second sub transistor STR2.

For example, the first width W1 and the second width W2 may be the same. As another example, the first width W1 and the second width W2 may be different from each other.

The first length L1 of the first gate portion 530_1 in the first direction may correspond to the first channel length of the first active layer 500 of the first sub transistor STR1, and the second length L2 of the second gate portion 530_2 in the first direction may correspond to the second channel length of the second active layer 700 of the second sub transistor STR2.

For example, the first length L1 and the second length L2 may be the same. As another example, the first length L1 and the second length L2 may be different from each other.

The first transistor TR1 may include a first sub transistor STR1 and a second sub transistor STR2 connected in parallel.

The channel width of the first transistor TR1 may be a sum of the first channel width and the second channel width, and the channel length of the first transistor TR1 may be the same as the first channel length or the second channel length.

Therefore, as the first transistor TR1 may include two sub transistors STR1 and STR2 connected in parallel, the channel length does not increase, but the channel width may increase compared to the case where one sub transistor STR1 may be included. For example, when the first width W1 and the second width W2 are the same, as the first transistor TR1 includes two sub transistors STR1 and STR2 connected in parallel, the channel width may be doubled, although the channel length remains unchanged, compared to the case where the first transistor TR1 may include one sub transistor STR1. Therefore, the performance of the first transistor TR1 may be enhanced. As a result, the first transistor TR1 may output a normal signal (e.g., a gate signal Vgate) at an accurate timing.

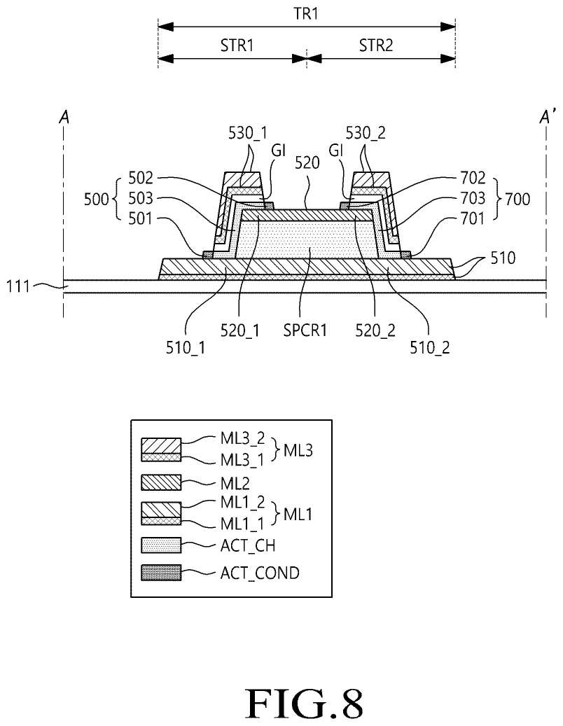

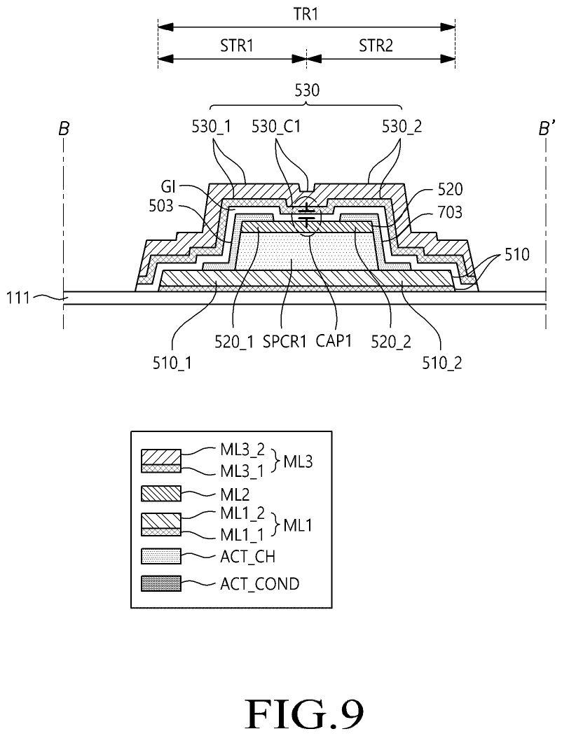

FIGS. 8 and 9 are cross-sectional views illustrating a first transistor TR1 including two sub transistors STR1 and STR2 in a display device 100 according to embodiments of the disclosure. In the following description, FIG. 5 is also referred to. FIG. 8 is a cross-sectional view taken along line A-A′ of FIG. 7, and FIG. 9 is a cross-sectional view taken along line B-B′ of FIG. 7.

The first transistor TR1 may include a drain electrode 510, a source electrode 520, a gate electrode 530, a first active layer 500, a second active layer 700, a first spacer SPCR1, and a gate insulation layer GI.

The drain electrode 510 may be disposed on the substrate 111 and may include a first drain portion 510_1 and a second drain portion 510_2.

The first spacer SPCR1 may be disposed on the drain electrode 510.

The source electrode 520 may be disposed on the first spacer SPCR1, and may include a first source portion 520_1 and a second source portion 520_2.

The first active layer 500 may include a first channel area 503, a first drain connection area 501 positioned on one side of the first channel area 503, and a first source connection area 502 positioned on the other side of the first channel area 503. For example, the first channel area 503 may include a semiconductor material ACT_CH forming a channel, and the first drain connection area 501 and the first source connection area 502 may include a conductive semiconductor material ACT_COND.

The first active layer 500 may extend from an upper surface of the first drain portion 510_1 to an upper surface of the first source portion 520_1 along a first side surface of the first spacer SPCR1. The first drain connection area 501 may be positioned on the upper surface of the first drain portion 510_1, the first source connection area 502 may be positioned on the upper surface of the first source portion 520_1, the first channel area 503 may connect the first drain connection area 501 and the first source connection area 502, and may be positioned on the first side surface of the first spacer SPRC1.

The second active layer 700 may include a second channel area 703, a second drain connection area 701 positioned on one side of the second channel area 703, and a second source connection area 702 positioned on the other side of the second channel area 703. For example, the second channel area 703 may include a semiconductor material ACT_CH forming a channel, and the second drain connection area 701 and the second source connection area 702 may include a conductive semiconductor material ACT_COND.

The second active layer 700 may extend from the upper surface of the second drain portion 510_2 to the upper surface of the second source portion 520_2 along the second side surface of the first spacer SPCR1. The second drain connection area 701 may be positioned on the upper surface of the second drain portion 510_2, the second source connection area 702 may be positioned on the upper surface of the second source portion 520_2, the second channel area 703 may connect the second drain connection area 701 to the second source connection area 702, and may be positioned on a second side surface of the first spacer SPRC1.

The gate insulation layer GI may be disposed on the first active layer 500 and the second active layer 700. The gate electrode 530 may be disposed on the gate insulation layer GI. The gate electrode 530 may include a first gate portion 530_1 overlapping the first channel area 503 of the first active layer 500 and a second gate portion 530_2 overlapping the second channel area 703 of the second active layer 700.

The first gate portion 530_1 may extend from the upper portion of the first drain portion 510_1 to the upper portion of the first source portion 520_1 along the first side surface of the first spacer SPCR1. The second gate portion 530_2 may extend from the upper portion of the second drain portion 510_2 to the upper portion of the second source portion 520_2 along the second side surface of the first spacer SPCR1.

The first transistor TR1 may include a first sub transistor STR1 including a first drain portion 510_1, a first source portion 520_1, a first gate portion 530_1, and a first active layer 500, and a second sub transistor STR2 including a second drain portion 510_2, a second source portion 520_2, a second gate portion 530_2, and a second active layer 700.

The first sub transistor STR1 and the second sub transistor STR2 included in the first transistor TR1 may be connected in parallel. Accordingly, the first transistor TR1 may have stable output characteristics.

The first transistor TR1 may be a transistor included in the gate driving circuit 130. When the gate driving circuit 130 is disposed in the non-display area NDA, the first transistor TR1 may be disposed in the non-display area NDA.

Each of the first sub transistor STR1 and the second sub transistor STR2 may be a vertical transistor. Accordingly, the size of the first transistor TR1 may be greatly reduced. Accordingly, the size of the gate driving circuit 130 including the first transistor TR1 may be greatly reduced. When the gate driving circuit 130 is disposed in the non-display area NDA, the size of the non-display area NDA may be greatly reduced.

With reference to FIG. 9, the display device 100 may further include a first capacitor CAP1 formed on the first spacer SPCR1. As the gate electrode 530 and the source electrode 520 overlap in the spaced space between the first active layer 500 and the second active layer 700, the first capacitor CAP1 may be formed.

As described above, by forming the first capacitor CAP1 using the gate electrode 530 and the source electrode 520 of the first transistor TR1, when the pull-up transistor Tu of FIG. 3 is the first transistor TR1, it is not necessary to separately form the capacitor CAP formed at the source node and the gate node of the pull-up transistor Tu. As a result, the size of the output buffer circuit 310 may be further reduced.

For example, the drain electrode 510 may be disposed in the first metal layer ML1, the source electrode 520 may be disposed in the second metal layer ML2, and the gate electrode 530 may be disposed in the third metal layer ML3. The second metal layer ML2 may be a metal layer between the first metal layer ML1 and the third metal layer ML3.

For example, the first metal layer ML1 may include a first lower metal layer ML1_1 and a first upper metal layer ML1_2. The third metal layer ML3 may include a third lower metal layer ML3_1 and a third upper metal layer ML3_2. The second metal layer ML2 may be a single metal layer. The first active layer 500 and the second active layer 700 of the first transistor TR1 may include the same semiconductor material as the active layer 560 of the second transistor TR2.

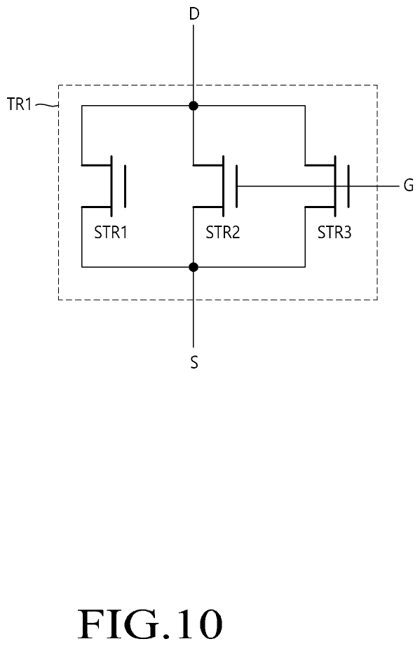

Hereinafter, the first transistor TR1 including three sub transistors is described with reference to FIGS. 10 to 13. In the following description, descriptions of the same contents as those described above may be omitted.

FIG. 10 illustrates a first transistor TR1 including three sub transistors STR1, STR2, and STR3 in a display device 100 according to embodiments of the disclosure.

As illustrated in FIG. 10, the first transistor TR1 may include a first sub transistor STR1, a second sub transistor STR2, and a third sub transistor STR3. The first sub transistor STR1, the second sub transistor STR2, and the third sub transistor STR3 included in the first transistor TR1 may be connected in parallel.

The respective drain nodes D of the first sub transistor STR1, the second sub transistor STR2, and the third sub transistor STR3 may be electrically connected, the respective source node S of the first sub transistor STR1, the second sub transistor STR2, and the third sub transistor STR3 may be electrically connected, and the respective gate nodes G of the first sub transistor STR1, the second sub transistor STR2, and the third sub transistor STR3 may be electrically connected.

The first sub transistor STR1, the second sub transistor STR2, and the third sub transistor STR3 may be simultaneously turned on or off. For example, each of the first sub transistor STR1, the second sub transistor STR2, and the third sub transistor STR3 may be a vertical transistor.

For example, the first transistor TR1 may be disposed in the non-display area NDA. For example, the first transistor TR1 may be a transistor included in the gate driving circuit 130. At least one of the transistors included in the gate driving circuit 130 may be the first transistor TR1. For example, at least one of the pull-up transistor Tu and the pull-down transistor Td included in the gate driving circuit 130 may be the first transistor TR1.

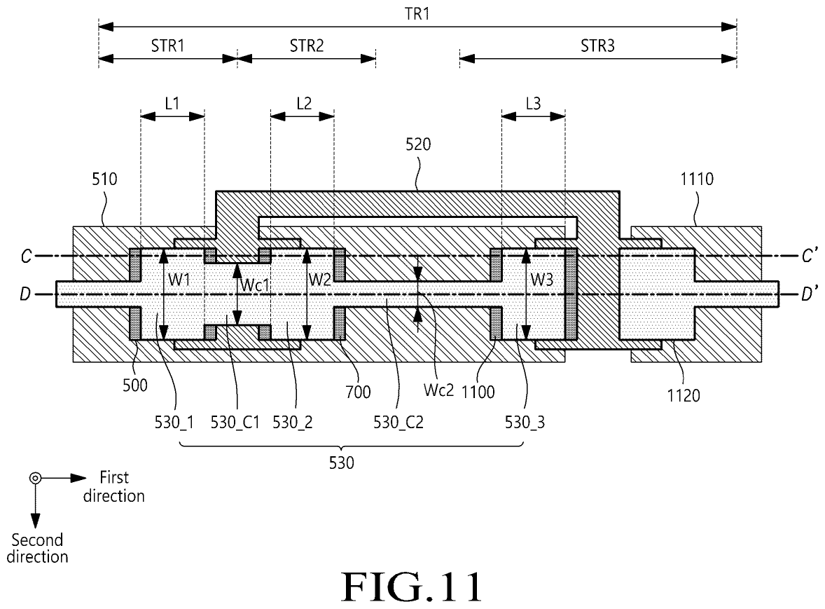

Hereinafter, a planar structure and a vertical structure of the first transistor TR1 of FIG. 10 are described with reference to FIGS. 11 to 13.

FIG. 11 is a plan view illustrating a first transistor TR1 including three sub transistors STR1, STR2, and STR3 in a display device 100 according to embodiments of the disclosure.

The first transistor TR1 may include a drain electrode 510 corresponding to the drain node D, a source electrode 520 corresponding to the source node S, and a gate electrode 530 corresponding to the gate node G, and may further include a first active layer 500, a second active layer 700, and a third active layer 1100.

Among the drain electrode 510, the source electrode 520, and the gate electrode 530, the drain electrode 510 may be widely disposed at the lowermost side. The source electrode 520 may be disposed on the drain electrode 510, and may overlap the drain electrode 510 in a vertical direction. The gate electrode 530 may be disposed on the drain electrode 510, and may overlap the drain electrode 510 in a vertical direction. The first active layer 500, the second active layer 700, and the third active layer 1100 may be disposed to be spaced apart from each other in the first direction (e.g., the row direction).

The gate electrode 530 includes a first gate portion 530_1 overlapping a portion (e.g., a first channel area) of the first active layer 500, a second gate portion 530_2 overlapping a portion (e.g., a second channel area) of the second active layer 700, a third gate portion 530_3 overlapping a portion (e.g., a third channel area) of the third active layer 1100, a first connection portion 530_C1 connecting the first gate portion 530_1 and the second gate portion 530_2, and a second connection portion 530_C2 connecting the second gate portion 530_2 and the third gate portion 530_3.

For example, the first gate portion 530_1, the first connection portion 530_C1, the second gate portion 530_2, the second connection portion 530_C2, and the third gate portion 530_3 may be arranged in the first direction (e.g., row direction).

An area where the first active layer 500 and the first gate portion 530_1 are disposed may correspond to an area of the first sub transistor STR1, an area where the second active layer 700 and the second gate portion 530_2 are disposed may correspond to an area of the second sub transistor STR2, and an area where the third active layer 1100 and the third gate portion 530_3 are disposed may correspond to an area of the third sub transistor STR3.

The first width W1 of the first gate portion 530_1 in the second direction may be wider than the first connection width Wc1 of the first connection portion 530_C1 in the second direction (W1>Wc1). The second width W2 of the second gate portion 530_2 in the second direction may be larger than the first connection width Wc1 of the first connection portion 530_C1 in the second direction (W2>Wc1).

The second width W2 of the second gate portion 530_2 in the second direction may be larger than the second connection width Wc2 of the second connection portion 530_C2 in the second direction (W2>Wc2). The third width W3 of the third gate portion 530_3 in the second direction may be larger than the second connection width Wc2 of the second connection portion 530_C2 in the second direction (W3>Wc2).

The first width W1 of the first gate portion 530_1 in the second direction may correspond to the first channel width of the first active layer 500 of the first sub transistor STR1, the second width W2 of the second gate portion 530_2 in the second direction may correspond to the second channel width of the second active layer 700 of the second sub transistor STR2, and the third width W3 of the third gate portion 530_3 in the second direction may correspond to the third channel width of the third active layer 1100 of the third sub transistor STR3.

For example, the first width W1, the second width W2, and the third width W3 may be the same. As another example, at least one of the first width W1, the second width W2, and the third width W3 may be different.

The first length L1 of the first gate portion 530_1 in the first direction may correspond to the first channel length of the first active layer 500 of the first sub transistor STR1, the second length L2 of the second gate portion 530_2 in the first direction may correspond to the second channel length of the second active layer 700 of the second sub transistor STR2, and the third length L3 of the third gate portion 530_3 in the first direction may correspond to the third channel length of the third active layer 1100 of the third sub transistor STR3.

For example, the first length L1, the second length L2, and the third length L3 may be the same. As another example, at least one of the first length L1, the second length L2, and the third length L3 may be different.

The first transistor TR1 may include a first sub transistor STR1, a second sub transistor STR2, and a third sub transistor STR3 connected in parallel. The channel width of the first transistor TR1 may be a sum of the first channel width, the second channel width, and the third channel width, and the channel length of the first transistor TR1 may be the same as one of the first channel length, the second channel length, and the third channel length.

Therefore, as the first transistor TR1 may include three sub transistors STR1, STR2, and STR3 connected in parallel, the channel length does not increase, but the channel width may increase compared to the case where one sub transistor STR1 may be included. For example, when the first width W1, the second width W2, and the third width W3 are the same, as the first transistor TR1 includes three sub transistors STR1, STR2, and STR3 connected in parallel, the channel width may be tripled, although the channel length remains unchanged, compared to the case where the first transistor TR1 may include one sub transistor STR1. Therefore, the performance of the first transistor TR1 may be further enhanced. As a result, the first transistor TR1 may output a more normal signal (e.g., the gate signal Vgate) at a more accurate timing.

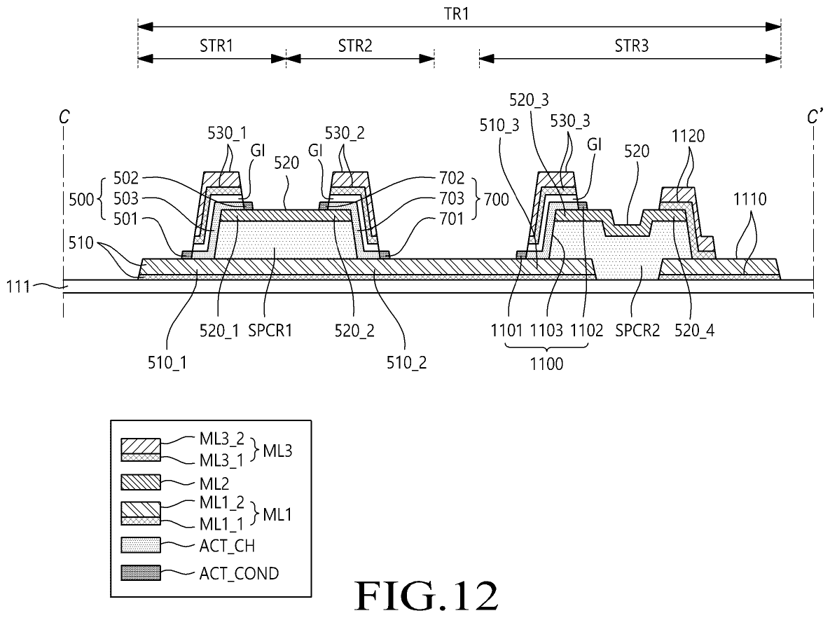

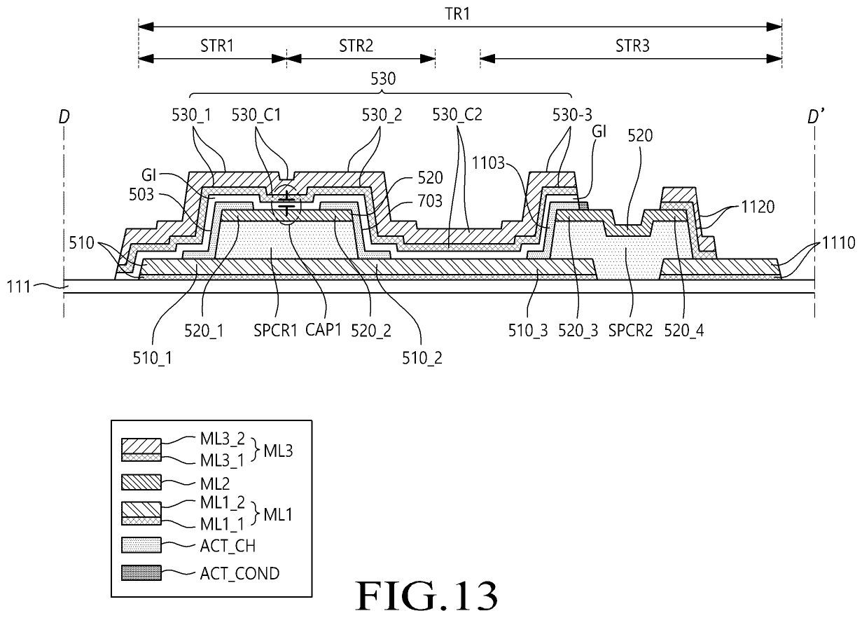

FIGS. 12 and 13 are cross-sectional views illustrating a first transistor TR1 including three sub transistors STR1, STR2, and STR3 in a display device 100 according to embodiments of the disclosure. FIG. 12 is a cross-sectional view taken along line C-C′ of FIG. 11, and FIG. 13 is a cross-sectional view taken along line D-D′ of FIG. 11.

The first transistor TR1 may include a drain electrode 510, a source electrode 520, a gate electrode 530, a first active layer 500, a second active layer 700, a third active layer 1100, a first spacer SPCR1, a second spacer SPCR2, and a gate insulation layer GI. The drain electrode 510 may be disposed on the substrate 111. The drain electrode 510 may include a first drain portion 510_1 and a second drain portion 510_2, and may further include a third drain portion 510_3.

The first spacer SPCR1 may be disposed on the drain electrode 510. The second spacer SPCR2 may be disposed on the substrate 111 and may be spaced apart from the first spacer SPCR1.

The source electrode 520 may be disposed on the first spacer SPCR1. The source electrode 520 may include a first source portion 520_1 and a second source portion 520_2, and may further include a third source portion 520_3.

The first active layer 500 may include a first channel area 503, a first drain connection area 501, and a first source connection area 502. For example, the first channel area 503 may include a semiconductor material ACT_CH forming a channel, and the first drain connection area 501 and the first source connection area 502 may include a conductive semiconductor material ACT_COND.

The first active layer 500 and the second active layer 700 may be formed as shown in FIGS. 8 and 9.

The third active layer 1100 may include a third channel area 1103, a third drain connection area 1101 positioned on one side of the third channel area 1103, and a third source connection area 1102 positioned on the other side of the third channel area 1103. For example, the third channel area 1103 may include a semiconductor material ACT_CH forming a channel, and the third drain connection area 1101 and the third source connection area 1102 may include a conductive semiconductor material ACT_COND. The third active layer 1100 may extend from the upper surface of the third drain portion 510_3 to the upper surface of the third source portion 520_3 along the first side surface of the second spacer SPCR2.

The gate insulation layer GI may be disposed on the first active layer 500, the second active layer 700, and the third active layer 1100. The gate electrode 530 may be disposed on the gate insulation layer GI. The gate electrode 530 may include a first gate portion 530_1 overlapping the first channel area 503 of the first active layer 500 and a second gate portion 530_2 overlapping the second channel area 703 of the second active layer 700, and may further include a third gate portion 530_3 overlapping the third channel area 1103 of the third active layer 1100.

The first transistor TR1 may include a first sub transistor STR1 including a first drain portion 510_1, a first source portion 520_1, a first gate portion 530_1, and a first active layer 500, a second sub transistor STR2 including a second drain portion 510_2, a second source portion 520_2, a second gate portion 530_2, and a second active layer 700, and a third sub transistor STR3 including a third drain portion 510_3, a third source portion 520_3, a third gate portion 530_3, and a third active layer 1100.

The first sub transistor STR1, the second sub transistor STR2, and the third sub transistor STR3 may be connected in parallel. Accordingly, the first transistor TR1 may have stable output characteristics.

The first transistor TR1 may be a transistor included in the gate driving circuit 130. When the gate driving circuit 130 is disposed in the non-display area NDA, the first transistor TR1 may be disposed in the non-display area NDA. Each of the first sub transistor STR1, the second sub transistor STR2, and the third sub transistor STR3 may be a vertical transistor.

Accordingly, the size of the first transistor TR1 may be greatly reduced. Accordingly, the size of the gate driving circuit 130 including the first transistor TR1 may be greatly reduced. When the gate driving circuit 130 is disposed in the non-display area NDA, the size of the non-display area NDA may be greatly reduced.

The display device 100 may further include a first capacitor CAP1 formed on the first spacer SPCR1. As the gate electrode 530 and the source electrode 520 overlap in the spaced space between the first active layer 500 and the second active layer 700, the first capacitor CAP1 may be formed.

As described above, by forming the first capacitor CAP1 using the gate electrode 530 and the source electrode 520 of the first transistor TR1, when the pull-up transistor Tu of FIG. 3 is the first transistor TR1, it is not necessary to separately form the capacitor CAP formed at the source node and the gate node of the pull-up transistor Tu. As a result, the size of the output buffer circuit 310 may be further reduced.

As illustrated in FIGS. 11 and 12, a display device 100 according to embodiments of the disclosure may further include an auxiliary source electrode 1110 spaced apart from the drain electrode 510, and a connection electrode 1120 disposed along a second side surface of a second spacer SPCR2 and electrically connecting the source electrode 520 on the second spacer SPCR2 to the auxiliary source electrode 1110.

As the first transistor TR1 further includes the auxiliary source electrode 1110 and the connection electrode 1120, the electrical stability of the source node S of the first transistor TR1 may be increased, thereby enhancing the output characteristics of the first transistor TR1.

The auxiliary source electrode 1110 may be disposed in the same first metal layer ML1 as the drain electrode 510. The source electrode 520 may be disposed in the second metal layer ML2. The connection electrode 1120 may be disposed in the same third metal layer ML3 as the gate electrode 530.

The second spacer SPCR2 may be disposed on a portion of the drain electrode 510 and a portion of the auxiliary source electrode 1110.

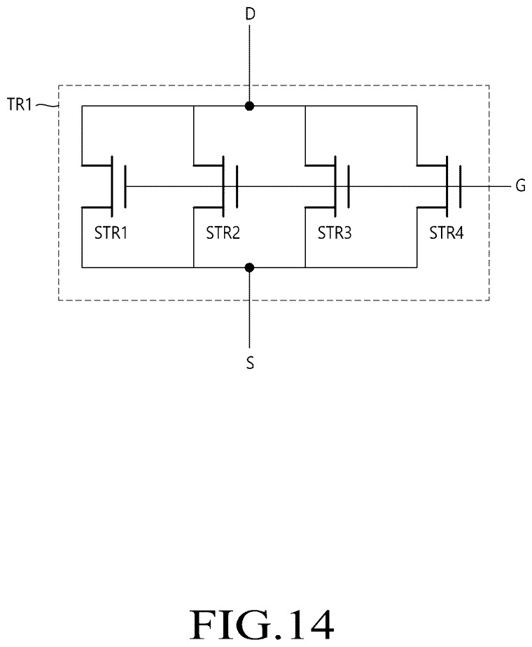

Hereinafter, the first transistor TR1 including four sub transistors is described with reference to FIGS. 14 to 17. In the following description, descriptions of the same contents as those described above may be omitted.

FIG. 14 illustrates a first transistor TR1 including four sub transistors STR1, STR2, STR3, and STR4 in a display device 100 according to embodiments of the disclosure.

The first transistor TR1 may include a first sub transistor STR1, a second sub transistor STR2, a third sub transistor STR3, and a fourth sub transistor STR4. The first sub transistor STR1, the second sub transistor STR2, the third sub transistor STR3, and the fourth sub transistor STR4 may be connected in parallel.

The respective drain nodes D of the first sub transistor STR1, the second sub transistor STR2, the third sub transistor STR3, and the fourth sub transistor STR4 may be electrically connected, the respective source node S of the first sub transistor STR1, the second sub transistor STR2, the third sub transistor STR3, and the fourth sub transistor STR4 may be electrically connected, and the respective gate nodes G of the first sub transistor STR1, the second sub transistor STR2, the third sub transistor STR3, and the fourth sub transistor STR4 may be electrically connected. The first sub transistor STR1, the second sub transistor STR2, the third sub transistor STR3, and the fourth sub transistor STR4 may be simultaneously turned on or off.

For example, each of the first sub transistor STR1, the second sub transistor STR2, the third sub transistor STR3, and the fourth sub transistor STR4 may be a vertical transistor. For example, the first transistor TR1 may be disposed in the non-display area NDA. For example, the first transistor TR1 may be a transistor included in the gate driving circuit 130. At least one of the transistors included in the gate driving circuit 130 may be the first transistor TR1. For example, at least one of the pull-up transistor Tu and the pull-down transistor Td included in the gate driving circuit 130 may be the first transistor TR1.

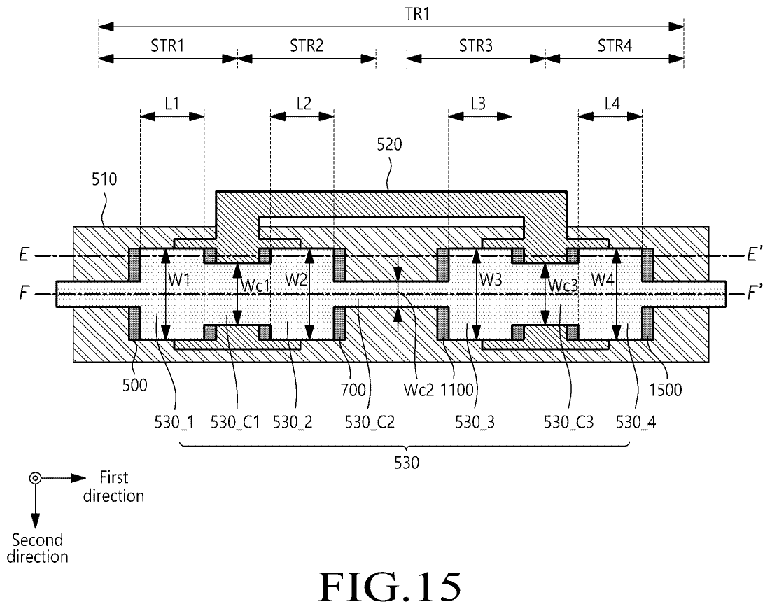

Hereinafter, a planar structure and a vertical structure of the first transistor TR1 of FIG. 14 are described with reference to FIGS. 15 to 17.

FIG. 15 is a plan view illustrating a first transistor TR1 including four sub transistors STR1, STR2, STR3, and STR4 in a display device 100 according to embodiments of the disclosure. The first transistor TR1 may include a drain electrode 510 corresponding to the drain node D, a source electrode 520 corresponding to the source node S, a gate electrode 530 corresponding to the gate node G, and may further include a first active layer 500, a second active layer 700, a third active layer 1100, and a fourth active layer 1500.

Among the drain electrode 510, the source electrode 520, and the gate electrode 530, the drain electrode 510 may be widely disposed at the lowermost side. The source electrode 520 may be disposed on the drain electrode 510, and may overlap the drain electrode 510 in a vertical direction. The gate electrode 530 may be disposed on the drain electrode 510, and may overlap the drain electrode 510 in a vertical direction.

The first active layer 500, the second active layer 700, the third active layer 1100, and the fourth active layer 1500 may be disposed to be spaced apart from each other in the first direction (e.g., the row direction).

The gate electrode 530 includes a first gate portion 530_1 overlapping a portion (e.g., a first channel area) of the first active layer 500, a second gate portion 530_2 overlapping a portion (e.g., a second channel area) of the second active layer 700, a third gate portion 530_3 overlapping a portion (e.g., a third channel area) of the third active layer 1100, a fourth gate portion 530_4 overlapping a portion (e.g., a fourth channel area) of the fourth active layer 1500, a first connection portion 530_C1 connecting the first gate portion 530_1 and the second gate portion 530_2, a second connection portion 530_C2 connecting the second gate portion 530_2 and the third gate portion 530_3, and a third connection portion 530_C3 connecting the third gate portion 530_3 and the fourth gate portion 530_4.

For example, the first gate portion 530_1, the first connection portion 530_C1, the second gate portion 530_2, the second connection portion 530_C2, the third gate portion 530_3, the third connection portion 530_C3, and the fourth gate portion 530_4 may be arranged in the first direction (e.g., the row direction).

An area where the first active layer 500 and the first gate portion 530_1 are disposed may correspond to an area of the first sub transistor STR1, an area where the second active layer 700 and the second gate portion 530_2 are disposed may correspond to an area of the second sub transistor STR2, an area where the third active layer 1100 and the third gate portion 530_3 are disposed may correspond to an area of the third sub transistor STR3, and an area where the fourth active layer 1500 and the fourth gate portion 530_4 are disposed may correspond to an area of the fourth sub transistor STR4.

The first width W1 of the first gate portion 530_1 in the second direction may be larger than the first connection width Wc1 of the first connection portion 530_C1 in the second direction (W1>Wc1). The second width W2 of the second gate portion 530_2 in the second direction may be larger than the first connection width Wc1 of the first connection portion 530_C1 in the second direction (W2>Wc1).

The second width W2 of the second gate portion 530_2 in the second direction may be larger than the second connection width Wc2 of the second connection portion 530_C2 in the second direction (W2>Wc2). The third width W3 of the third gate portion 530_3 in the second direction may be larger than the second connection width Wc2 of the second connection portion 530_C2 in the second direction (W3>Wc2).

The third width W3 of the third gate portion 530_3 in the second direction may be larger than the third connection width Wc3 of the third connection portion 530_C3 in the second direction (W3>Wc3). The fourth width W4 of the fourth gate portion 530_4 in the second direction may be larger than the third connection width Wc3 of the third connection portion 530_C3 in the second direction (W4>Wc3).

The first width W1 of the first gate portion 530_1 in the second direction may correspond to the first channel width of the first active layer 500 of the first sub transistor STR1, the second width W2 of the second gate portion 530_2 in the second direction may correspond to the second channel width of the second active layer 700 of the second sub transistor STR2, the third width W3 of the third gate portion 530_3 in the second direction may correspond to the third channel width of the third active layer 1100 of the third sub transistor STR3, and the fourth width W4 of the fourth gate portion 530_4 in the second direction may correspond to the fourth channel width of the fourth active layer 1500 of the fourth sub transistor STR4.

For example, the first width W1, the second width W2, the third width W3, and the fourth width W4 may be the same. As another example, at least one of the first width W1, the second width W2, the third width W3, and the fourth width W4 may be different.

The first length L1 of the first gate portion 530_1 in the first direction may correspond to the first channel length of the first active layer 500 of the first sub transistor STR1, the second length L2 of the second gate portion 530_2 in the first direction may correspond to the second channel length of the second active layer 700 of the second sub transistor STR2, the third length L3 of the third gate portion 530_3 in the first direction may correspond to the third channel length of the third active layer 1100 of the third sub transistor STR3, and the fourth length L4 of the fourth gate portion 530_4 in the first direction may correspond to the fourth channel length of the fourth active layer 1500 of the fourth sub transistor STR4. For example, the first length L1, the second length L2, the third length L3, and the fourth length L4 may be the same. As another example, at least one of the first length L1, the second length L2, the third length L3, and the fourth length L4 may be different.

The first transistor TR1 may include a first sub transistor STR1, a second sub transistor STR2, a third sub transistor STR3, and a fourth sub transistor STR4 connected in parallel. The channel width of the first transistor TR1 may be a sum of the first channel width, the second channel width, the third channel width, and the fourth channel width, and the channel length of the first transistor TR1 may be the same as at least one of the first channel length, the second channel length, the third channel length, and the fourth channel length.

Therefore, as the first transistor TR1 may include four sub transistors STR1, STR2, STR3, and STR4 connected in parallel, the channel length does not increase, but the channel width may increase compared to the case where one sub transistor STR1 may be included. For example, when the first width W1, the second width W2, the third width W3, and the fourth width W4 are the same, as the first transistor TR1 includes four sub transistors STR1, STR2, STR3, and STR4 connected in parallel, the channel width may be quadrupled, although the channel length remains unchanged, compared to the case where the first transistor TR1 may include one sub transistor STR1. Therefore, the performance of the first transistor TR1 may be much further enhanced. As a result, the first transistor TR1 may output a more normal signal (e.g., the gate signal Vgate) at a more accurate timing.

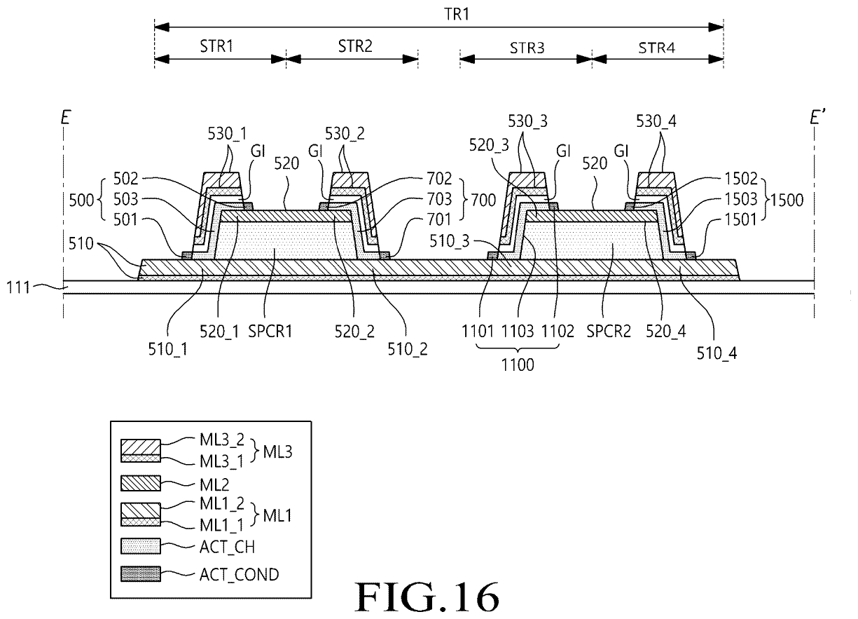

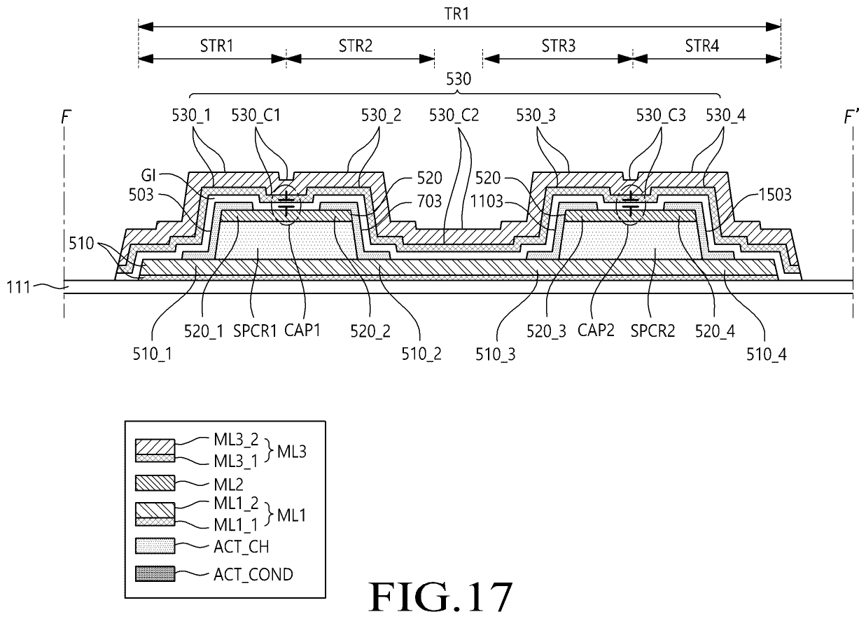

FIGS. 16 and 17 are cross-sectional views illustrating a first transistor TR1 including four sub transistors STR1, STR2, STR3, and STR4 in a display device 100 according to embodiments of the disclosure. FIG. 16 is a cross-sectional view taken along line E-E′ of FIG. 15, and FIG. 17 is a cross-sectional view taken along line F-F′ of FIG. 15.

The first transistor TR1 may include a drain electrode 510, a source electrode 520, a gate electrode 530, a first active layer 500, a second active layer 700, a third active layer 1100, a fourth active layer 1500, a first spacer SPCR1, a second spacer SPCR2, and a gate insulation layer GI. The drain electrode 510 may be disposed on the substrate 111. The drain electrode 510 may include a first drain portion 510_1 and a second drain portion 510_2, and may further include a third drain portion 510_3 and a fourth drain portion 510_4.

The first spacer SPCR1 may be disposed on the drain electrode 510. The second spacer SPCR2 may be disposed on the substrate 111 and may be spaced apart from the first spacer SPCR1. The source electrode 520 may be disposed on the first spacer SPCR1. The source electrode 520 may include a first source portion 520_1 and a second source portion 520_2, and may further include a third source portion 520_3 and a fourth source portion 520_4.

The first active layer 500 and the second active layer 700 may be formed as shown in FIGS. 8 and 9.

The third active layer 1100 may include a third channel area 1103, a third drain connection area 1101, and a third source connection area 1102. The third active layer 1100 may extend from the upper surface of the third drain portion 510_3 to the upper surface of the third source portion 520_3 along the first side surface of the second spacer SPCR2.

The fourth active layer 1500 may include a fourth channel area 1503, a fourth drain connection area 1501 positioned on one side of the fourth channel area 1503, and a fourth source connection area 1502 positioned on the other side of the fourth channel area 1503. The fourth active layer 1500 may extend from the upper surface of the fourth drain portion 510_4 to the upper surface of the fourth source portion 520_4 along the second side surface of the second spacer SPCR2.

The gate insulation layer GI may be disposed on the first active layer 500, the second active layer 700, the third active layer 1100, and the fourth active layer 1500.

The gate electrode 530 may be disposed on the gate insulation layer GI. The gate electrode 530 may include a first gate portion 530_1 overlapping the first channel area 503 of the first active layer 500 and a second gate portion 530_2 overlapping the second channel area 703 of the second active layer 700. The gate electrode 530 may further include a third gate portion 530_3 overlapping the third channel area 1103 of the third active layer 1100 and a fourth gate portion 530_4 overlapping the fourth channel area 1503 of the fourth active layer 1500.

The first transistor TR1 may include a first sub transistor STR1, a second sub transistor STR2, a third sub transistor STR3, and a fourth sub transistor STR4. The first sub transistor STR1 may include a first drain portion 510_1, a first source portion 520_1, a first gate portion 530_1, and a first active layer 500. The second sub transistor STR2 may include a second drain portion 510_2, a second source portion 520_2, a second gate portion 530_2, and a second active layer 700. The third sub transistor STR3 may include a third drain portion 510_3, a third source portion 520_3, a third gate portion 530_3, and a third active layer 1100. The fourth sub transistor STR4 may include a fourth drain portion 510_4, a fourth source portion 520_4, a fourth gate portion 530_4, and a fourth active layer 1500. The first sub transistor STR1, the second sub transistor STR2, the third sub transistor STR3, and the fourth sub transistor STR4 may be connected in parallel. Accordingly, the first transistor TR1 may have stable output characteristics.

The display device 100 may further include a first capacitor CAP1 formed on the first spacer SPCR1 and a second capacitor CAP2 formed on the second spacer SPCR2. As the gate electrode 530 and the source electrode 520 overlap in the spaced space between the first active layer 500 and the second active layer 700, the first capacitor CAP1 may be formed. The gate electrode 530 and the source electrode 520 overlap in a space spaced apart from the third active layer 1100 and the fourth active layer 1500, thereby forming the second capacitor CAP2.

The first capacitor CAP1 and the second capacitor CAP2 may be connected in parallel between the gate electrode 530 and the source electrode 520. The capacitor formed between the source node S and the gate node G of the first transistor TR1 may include the first capacitor CAP1 and the second capacitor CAP2 connected in parallel. Therefore, the capacitance of the capacitor formed between the source node S and the gate node G of the first transistor TR1 may increase.

As the first capacitor CAP1 and the second capacitor CAP2 connected in parallel between the gate electrode 530 and the source electrode 520 of the first transistor TR1 are formed, when the pull-up transistor Tu of FIG. 3 is implemented as the first transistor TR1, the boosting performance of the capacitor CAP connected to the source node and the gate node of the pull-up transistor Tu may be enhanced, significantly enhancing the output characteristics of the gate signal Vgate.

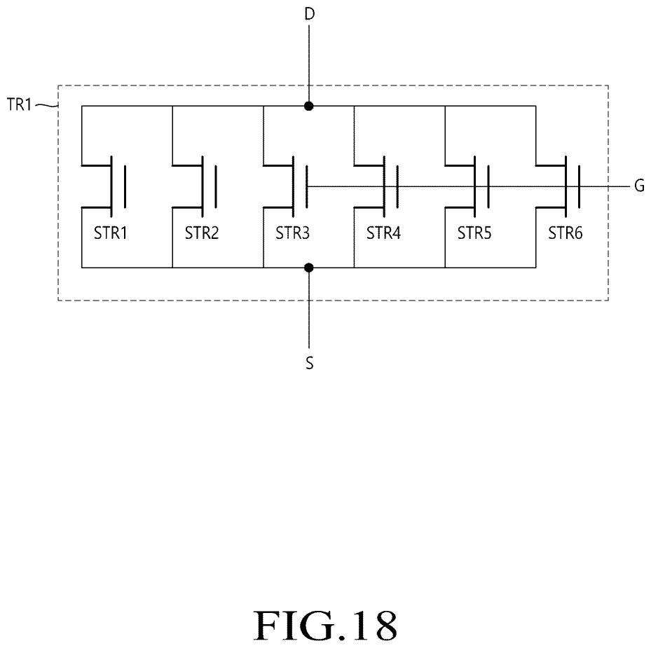

Hereinafter, the first transistor TR1 including six sub transistors is described with reference to FIGS. 18 to 21. In the following description, descriptions of the same contents as those described above may be omitted.

FIG. 18 illustrates a first transistor TR1 including six sub transistors STR1, STR2, STR3, STR4, STR5, and STR6 in a display device 100 according to embodiments of the disclosure. The first transistor TR1 may include a first sub transistor STR1, a second sub transistor STR2, a third sub transistor STR3, a fourth sub transistor STR4, a fifth sub transistor STR5, and a sixth sub transistor STR6.

The first sub transistor STR1, the second sub transistor STR2, the third sub transistor STR3, the fourth sub transistor STR4, the fifth sub transistor STR5, and the sixth sub transistor STR6 included in the first transistor TR1 may be connected in parallel. The respective drain nodes D of the first sub transistor STR1, the second sub transistor STR2, the third sub transistor STR3, the fourth sub transistor STR4, the fifth sub transistor STR5, and the sixth sub transistor STR6 may be electrically connected to each other. The respective source nodes S of the first sub transistor STR1, the second sub transistor STR2, the third sub transistor STR3, the fourth sub transistor STR4, the fifth sub transistor STR5, and the sixth sub transistor STR6 may be electrically connected to each other. The respective gate nodes G of the first sub transistor STR1, the second sub transistor STR2, the third sub transistor STR3, the fourth sub transistor STR4, the fifth sub transistor STR5, and the sixth sub transistor STR6 may be electrically connected to each other. The first sub transistor STR1, the second sub transistor STR2, the third sub transistor STR3, the fourth sub transistor STR4, the fifth sub transistor STR5, and the sixth sub transistor STR6 may be simultaneously turned on or off.

For example, each of the first sub transistor STR1, the second sub transistor STR2, the third sub transistor STR3, the fourth sub transistor STR4, the fifth sub transistor STR5, and the sixth sub transistor STR6 may be a vertical transistor.

For example, the first transistor TR1 may be disposed in the non-display area NDA. For example, the first transistor TR1 may be a transistor included in the gate driving circuit 130. At least one of the transistors included in the gate driving circuit 130 may be the first transistor TR1. For example, at least one of the pull-up transistor Tu and the pull-down transistor Td included in the gate driving circuit 130 may be the first transistor TR1.

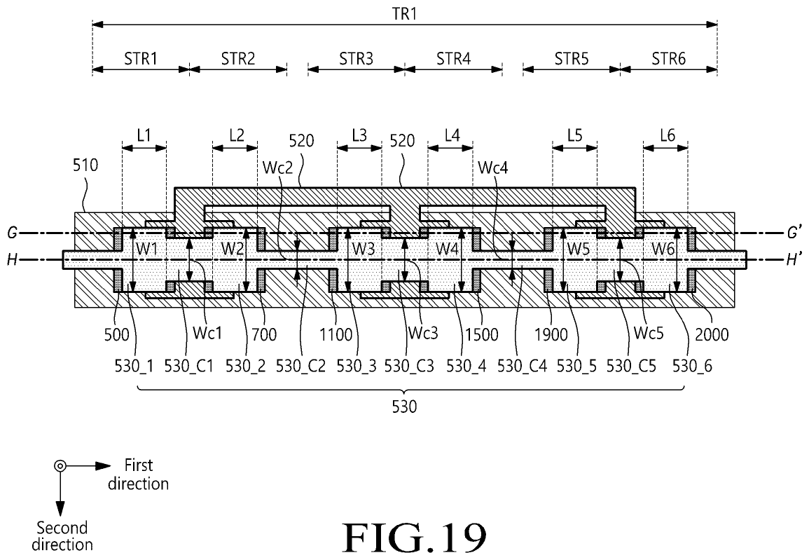

Hereinafter, a planar structure and a vertical structure of the first transistor TR1 of FIG. 18 are described with reference to FIGS. 19 to 21.

FIG. 19 is a plan view illustrating a first transistor TR1 including six sub transistors STR1, STR2, STR3, STR4, STR5, and STR6 in a display device 100 according to embodiments of the disclosure.

The first transistor TR1 may include a drain electrode 510 corresponding to the drain node D, a source electrode 520 corresponding to the source node S, and a gate electrode 530 corresponding to the gate node G. The first transistor TR1 may further include a first active layer 500, a second active layer 700, a third active layer 1100, a fourth active layer 1500, a fifth active layer 1900, and a sixth active layer 2000.

Among the drain electrode 510, the source electrode 520, and the gate electrode 530, the drain electrode 510 may be widely disposed at the lowermost side. The source electrode 520 may be disposed on the drain electrode 510, and may overlap the drain electrode 510 in a vertical direction. The gate electrode 530 may be disposed on the drain electrode 510, and may overlap the drain electrode 510 in a vertical direction.

The first active layer 500, the second active layer 700, the third active layer 1100, the fourth active layer 1500, the fifth active layer 1900, and the sixth active layer 2000 may be disposed to be spaced apart from each other in the first direction (e.g., the row direction).

The gate electrode 530 may include a first gate portion 530_1 overlapping a portion (e.g., a first channel area) of the first active layer 500, a second gate portion 530_2 overlapping a portion (e.g., a second channel area) of the second active layer 700, a third gate portion 530_3 overlapping a portion (e.g., a third channel area) of the third active layer 1100, a fourth gate portion 530_4 overlapping a portion (e.g., a fourth channel area) of the fourth active layer 1500, a fifth gate portion 530_5 overlapping a portion (e.g., a fifth channel area) of the fifth active layer 1900, and a sixth gate portion 530_6 overlapping a portion (e.g., a sixth channel area) of the sixth active layer 2000.

The gate electrode 530 may further include a first connection portion 530_C1 connecting the first gate portion 530_1 and the second gate portion 530_2, a second connection portion 530_C2 connecting the second gate portion 530_2 and the third gate portion 530_3, a third connection portion 530_C3 connecting the third gate portion 530_3 and the fourth gate portion 530_4, a fourth connection portion 530_C4 connecting the fourth gate portion 530_4 and the fifth gate portion 530_5, and a fifth connection portion 530_C5 connecting the fifth gate portion 530_5 and the sixth gate portion 530_6. For example, the first gate portion 530_1, the first connection portion 530_C1, the second gate portion 530_2, the second connection portion 530_C2, the third gate portion 530_3, the third connection portion 530_C3, the fourth gate portion 530_4, the fourth connection portion 530_C4, the fifth gate portion 530_5, the fifth connection portion 530_C5, and the sixth gate portion 530_6 may be arranged in the first direction (e.g., the row direction).

An area where the first active layer 500 and the first gate portion 530_1 are disposed may correspond to an area of the first sub transistor STR1, an area where the second active layer 700 and the second gate portion 530_2 are disposed may correspond to an area of the second sub transistor STR2, an area where the third active layer 1100 and the third gate portion 530_3 are disposed may correspond to an area of the third sub transistor STR3, an area where the fourth active layer 1500 and the fourth gate portion 530_4 are disposed may correspond to an area of the fourth sub transistor STR4, an area where the fifth active layer 1900 and the fifth gate portion 530_5 are disposed may correspond to an area of the fifth sub transistor STR5, and an area where the sixth active layer 2000 and the sixth gate portion 530_6 are disposed may correspond to an area of the sixth sub transistor STR6.

The first width W1 of the first gate portion 530_1 in the second direction may be larger than the first connection width Wc1 of the first connection portion 530_C1 in the second direction (W1>Wc1). The second width W2 of the second gate portion 530_2 in the second direction may be larger than the first connection width Wc1 of the first connection portion 530_C1 in the second direction (W2>Wc1).

The second width W2 of the second gate portion 530_2 in the second direction may be larger than the second connection width Wc2 of the second connection portion 530_C2 in the second direction (W2>Wc2). The third width W3 of the third gate portion 530_3 in the second direction may be larger than the second connection width Wc2 of the second connection portion 530_C2 in the second direction (W3>Wc2).

The third width W3 of the third gate portion 530_3 in the second direction may be larger than the third connection width Wc3 of the third connection portion 530_C3 in the second direction (W3>Wc3). The fourth width W4 of the fourth gate portion 530_4 in the second direction may be larger than the third connection width Wc3 of the third connection portion 530_C3 in the second direction (W4>Wc3).

The fourth width W4 of the fourth gate portion 530_4 in the second direction may be larger than the fourth connection width Wc4 in the second direction of the fourth connection portion 530_C4 (W4>Wc4). The fifth width W5 of the fifth gate portion 530_5 in the second direction may be larger than the fourth connection width Wc4 in the second direction of the fourth connection portion 530_C4 (W5>Wc4).

The fifth width W5 of the fifth gate portion 530_5 in the second direction may be larger than the fifth connection width Wc5 in the second direction of the fifth connection portion 50_C5 (W 5>Wc5). The sixth width W6 of the sixth gate portion 530_6 in the second direction may be larger than the fifth connection width Wc5 in the second direction of the fifth connection portion 530_C5 (W 6>Wc5).

The first width W1 of the first gate portion 530_1 in the second direction may correspond to the first channel width of the first active layer 500 of the first sub transistor STR1, the second width W2 of the second gate portion 530_2 in the second direction may correspond to the second channel width of the second active layer 700 of the second sub transistor STR2, the third width W3 of the third gate portion 530_3 in the second direction may correspond to the third channel width of the third active layer 1100 of the third sub transistor STR3, the fourth width W4 of the fourth gate portion 530_4 in the second direction may correspond to the fourth channel width of the fourth active layer 1500 of the fourth sub transistor STR4, the fifth width W5 of the fifth gate portion 530_5 in the second direction may correspond to the fifth channel width of the fifth active layer 1900 of the fifth sub transistor STR5, and the sixth width W6 of the sixth gate portion 530_6 in the second direction may correspond to the sixth channel width of the sixth active layer 2000 of the sixth sub transistor STR6.

For example, the first width W1, the second width W2, the third width W3, the fourth width W4, the fifth width W5, and the sixth width W6 may be the same. As another example, at least one of the first width W1, the second width W2, the third width W3, the fourth width W4, the fifth width W5, and the sixth width W6 may be different.

The first length L1 of the first gate portion 530_1 in the first direction may correspond to the first channel length of the first active layer 500 of the first sub transistor STR1, the second length L2 of the second gate portion 530_2 in the first direction may correspond to the second channel length of the second active layer 700 of the second sub transistor STR2, the third length L3 of the third gate portion 530_3 in the first direction may correspond to the third channel length of the third active layer 1100 of the third sub transistor STR3, the fourth length L4 of the fourth gate portion 530_4 in the first direction may correspond to the fourth channel length of the fourth active layer 1500 of the fourth sub transistor STR4, the fifth length L5 of the fifth gate portion 530_5 in the first direction may correspond to the fifth channel length of the fifth active layer 1900 of the fifth sub transistor STR5, and the sixth length L6 of the sixth gate portion 530_6 in the first direction may correspond to the sixth channel length of the sixth active layer 2000 of the sixth sub transistor STR6.

For example, the first length L1, the second length L2, the third length L3, the fourth length L4, the fifth length L5, and the sixth length L6 may be the same. As another example, at least one of the first length L1, the second length L2, the third length L3, the fourth length L4, the fifth length L5, and the sixth length L6 may be different.

The first transistor TR1 may include the first sub transistor STR1, the second sub transistor STR2, the third sub transistor STR3, the fourth sub transistor STR4, the fifth sub transistor STR5, and the sixth sub transistor STR6, connected in parallel. The channel width of the first transistor TR1 may be a sum of the first channel width, the second channel width, the third channel width, the fourth channel width, the fifth channel width, and the sixth channel width, and the channel length of the first transistor TR1 may be the same as at least one of the first channel length, the second channel length, the third channel length, the fourth channel length, the fifth channel length, and the sixth channel length.

Therefore, as the first transistor TR1 may include six sub transistors STR1, STR2, STR3, STR4, STR5, and STR6 connected in parallel, the channel length does not increase, but the channel width may increase compared to the case where one sub transistor STR1 may be included. For example, when the first width W1, the second width W2, the third width W3, the fourth width W4, the fifth width W5, and the sixth width W6 are the same, as the first transistor TR1 includes six sub transistors STR1, STR2, STR3, STR4, STR5, and STR6 connected in parallel, the channel width may be increased by six times, although the channel length remains unchanged, compared to the case where the first transistor TR1 may include one sub transistor STR1. Therefore, the performance of the first transistor TR1 may be much further enhanced. As a result, the first transistor TR1 may output a more normal signal (e.g., the gate signal Vgate) at a more accurate timing.

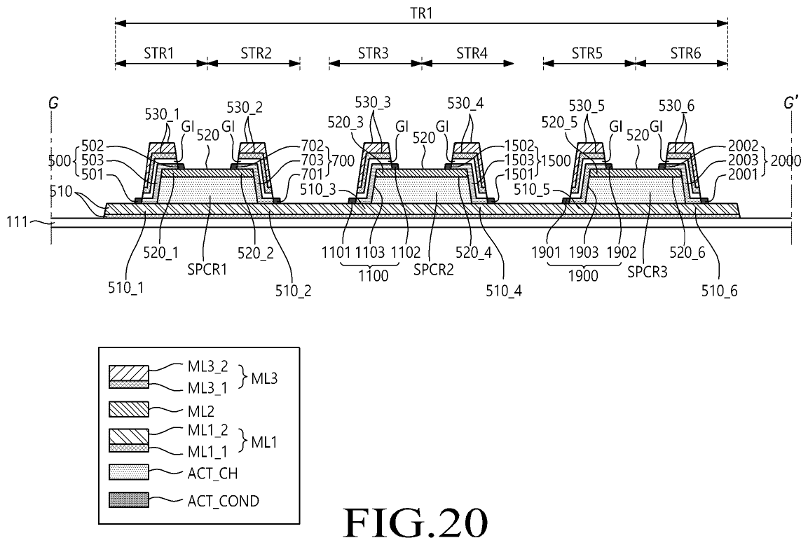

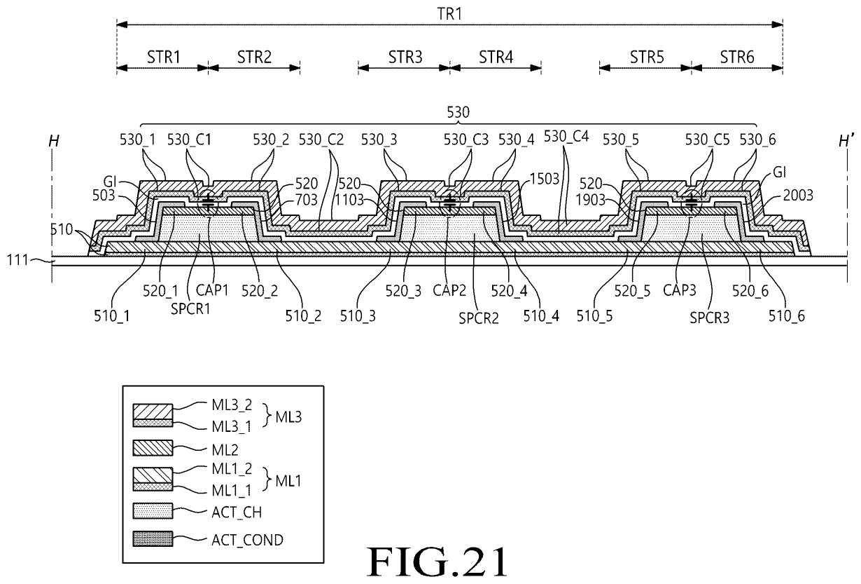

FIGS. 20 and 21 are cross-sectional views illustrating a first transistor TR1 including six sub transistors STR1, STR2, STR3, STR4, STR5, and STR6 in a display device 100 according to embodiments of the disclosure. FIG. 20 is a cross-sectional view taken along line G-G′ of FIG. 19, and FIG. 21 is a cross-sectional view taken along line H-H′ of FIG. 19.

The first transistor TR1 may include a drain electrode 510, a source electrode 520, a gate electrode 530, a first active layer 500, a second active layer 700, a third active layer 1100, a fourth active layer 1500, a fifth active layer 1900, a sixth active layer 2000, a first spacer SPCR1, a second spacer SPCR2, a third spacer SPCR3, and a gate insulation layer GI. The drain electrode 510 may include a first drain portion 510_1, a second drain portion 510_2, a third drain portion 510_3, and a fourth drain portion 510_4, and may further include a fifth drain portion 510_5 and a sixth drain portion 510_6.

The first spacer SPCR1, the second spacer SPCR2, and the third spacer SPCR3 may be disposed on the drain electrode 510. The first spacer SPCR1, the second spacer SPCR2, and the third spacer SPCR3 may be spaced apart from each other. The source electrode 520 may include a first source portion 520_1, a second source portion 520_2, a third source portion 520_3, and a fourth source portion 520_4, and may further include a fifth source portion 520_5 and a sixth source portion 520_6.

The first active layer 500, the second active layer 700, the third active layer 1100, and the fourth active layer 1500 may be formed as shown in FIGS. 16 and 17.

The fifth active layer 1900 may include a fifth channel area 1903, a fifth drain connection area 1901 positioned on one side of the fifth channel area 1903, and a fifth source connection area 1902 positioned on the other side of the fifth channel area 1903. The fifth active layer 1900 may extend from the upper surface of the fifth drain portion 510_5 to the upper surface of the fifth source portion 520_5 along the first side surface of the third spacer SPCR3.

The sixth active layer 2000 may include a sixth channel area 2003, a sixth drain connection area 2001 positioned on one side of the sixth channel area 2003, and a sixth source connection area 2002 positioned on the other side of the sixth channel area 2003. The sixth active layer 2000 may extend from the upper surface of the sixth drain portion 510_6 to the upper surface of the sixth source portion 520_6 along the second side surface of the third spacer SPCR3.

The gate insulation layer GI may be disposed on the first active layer 500, the second active layer 700, the third active layer 1100, the fourth active layer 1500, the fifth active layer 1900, and the sixth active layer 2000. The gate electrode 530 may be disposed on the gate insulation layer GI.

The gate electrode 530 may include a first gate portion 530_1 overlapping the first channel area 503 of the first active layer 500, a second gate portion 530_2 overlapping the second channel area 703 of the second active layer 700, a third gate portion 530_3 overlapping the third channel area 1103 of the third active layer 1100, and a fourth gate portion 530_4 overlapping the fourth channel area 1503 of the fourth active layer 1500. The gate electrode 530 may further include a fifth gate portion 530_5 overlapping the fifth channel area 1903 of the fifth active layer 1900 and a sixth gate portion 530_6 overlapping the sixth channel area 2003 of the sixth active layer 2000.

The first transistor TR1 may include first to sixth sub transistors STR1, STR2, STR3, STR4, STR5, and STR6.

The first sub transistor STR1 may include a first drain portion 510_1, a first source portion 520_1, a first gate portion 530_1, and a first active layer 500. The second sub transistor STR2 may include a second drain portion 510_2, a second source portion 520_2, a second gate portion 530_2, and a second active layer 700. The third sub transistor STR3 may include a third drain portion 510_3, a third source portion 520_3, a third gate portion 530_3, and a third active layer 1100. The fourth sub transistor STR4 may include a fourth drain portion 510_4, a fourth source portion 520_4, a fourth gate portion 530_4, and a fourth active layer 1500. The fifth sub transistor STR5 may include a fifth drain portion 510_5, a fifth source portion 520_5, a fifth gate portion 530_5, and a fifth active layer 1900. The sixth sub transistor STR6 may include a sixth drain portion 510_6, a sixth source portion 520_6, a sixth gate portion 530_6, and a sixth active layer 2000. The first sub transistor STR1, the second sub transistor STR2, the third sub transistor STR3, the fourth sub transistor STR4, the fifth sub transistor STR5, and the sixth sub transistor STR6 may be connected in parallel.

The display device 100 according to embodiments of the disclosure may include a first capacitor CAP1 formed on the first spacer SPCR1, a second capacitor CAP2 formed on the second spacer SPCR2, and a third capacitor CAP3 formed on the third spacer SPCR3. As the gate electrode 530 and the source electrode 520 overlap in the spaced space between the first active layer 500 and the second active layer 700, the first capacitor CAP1 may be formed.

The gate electrode 530 and the source electrode 520 overlap in a space spaced apart from the third active layer 1100 and the fourth active layer 1500, thereby forming the second capacitor CAP2.

The gate electrode 530 and the source electrode 520 overlap in the spaced space between the fifth active layer 1900 and the sixth active layer 2000, forming the third capacitor CAP3.

The first capacitor CAP1, the second capacitor CAP2, and the third capacitor CAP3 may be connected in parallel between the gate electrode 530 and the source electrode 520. The capacitor formed between the source node S and the gate node G of the first transistor TR1 may include the first capacitor CAP1, the second capacitor CAP2, and the third capacitor CAP3 connected in parallel. Therefore, the capacitance of the capacitor formed between the source node S and the gate node G of the first transistor TR1 may increase.

As the first capacitor CAP1, the second capacitor CAP2, and the third capacitor CAP3 connected in parallel between the gate electrode 530 and the source electrode 520 of the first transistor TR1 are formed, when the pull-up transistor Tu of FIG. 3 is implemented as the first transistor TR1, the boosting performance of the capacitor CAP connected to the source node and the gate node of the pull-up transistor Tu may be enhanced, significantly enhancing the output characteristics of the gate signal Vgate.

According to embodiments of the disclosure described above, there may be provided a display device including a transistor having a structure that may be disposed in a small area.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate; and
a first transistor on the substrate, wherein the first transistor includes:
a drain electrode on the substrate and including a first drain portion and a second drain portion,
a first spacer on the drain electrode at a portion between the first drain portion and second drain portion,
a source electrode on an upper surface of the first spacer, the source electrode including a first source portion and a second source portion,
a first active layer extending from an upper surface of the first drain portion to an upper surface of the first source portion along a first side surface of the first spacer,
a second active layer extending from an upper surface of the second drain portion to an upper surface of the second source portion along a second side surface of the first spacer,
a gate insulation layer on the first active layer and the second active layer, and
a gate electrode on the gate insulation layer and including a first gate portion overlapping a first channel area of the first active layer and a second gate portion overlapping a second channel area of the second active layer.

2. The display device of claim 1, wherein a portion of the first active layer contacting the upper surface of first source portion is vertically over the first source portion,
wherein a first source portion is vertically over the drain electrode with the spacer vertically between the first source portion and drain electrode,
wherein a portion of the second active layer contacting the upper surface of second source portion is vertically over the second source portion, and
wherein a second source portion is vertically over the drain electrode with the spacer vertically between the second source portion and drain electrode.

3. The display device of claim 1, wherein the substrate includes a display area displaying an image and a non-display area outside the display area, and wherein the first transistor is in the non-display area.

4. The display device of claim 1, further comprising a second transistor on the substrate, wherein the second transistor includes:
an active layer on the substrate and including a channel area, a first connection area at one side of the channel area, and a second connection area at another side of the channel area;
a first electrode connected to the first connection area;
a second electrode connected to the second connection area; and
a third electrode on the gate insulation layer on the channel area and overlapping the channel area.

5. The display device of claim 4, further comprising:
a gate line on the substrate;
a subpixel on the substrate and connected to the gate line; and
a gate driving circuit on the substrate and outputting a gate signal having a turn-on level voltage or a turn-off level voltage to the gate line,
wherein the first transistor is included in the gate driving circuit, and
wherein the second transistor is included in the subpixel.

6. The display device of claim 4, wherein the first transistor has an area in a plan view smaller than an area in the plan view of the second transistor, and
wherein the first transistor has a mobility larger than a mobility of the second transistor.

7. The display device of claim 4, further comprising:
a buffer layer between the substrate and the second transistor; and
a shield pattern between the substrate and the buffer layer, the shield pattern in a first metal layer and overlapping at least a portion of the second transistor,
wherein the drain electrode is in the first metal layer, and
wherein the first spacer includes a same insulating material as the buffer layer, and the first spacer has a thickness larger than a thickness of the buffer layer.

8. The display device of claim 7, wherein the source electrode is in a second metal layer of a different layer of the first electrode, the second electrode, and the third electrode,
wherein the gate electrode is in a third metal layer, at least one of the first electrode, the second electrode, and the third electrode being in the third metal layer,
wherein the second metal layer is between the first metal layer and the third metal layer, and
wherein the first active layer and the second active layer include a same semiconductor material as the active layer.

9. The display device of claim 1, further comprising a first capacitor on the first spacer, wherein the first capacitor is between the gate electrode and the source electrode in a space where the first active layer and the second active layer are spaced apart.

10. The display device of claim 1, wherein the drain electrode further includes a third drain portion,
wherein the source electrode further includes a third source portion,
wherein the first transistor further includes a second spacer on the substrate and spaced apart from the first spacer, and a third active layer extending from an upper surface of the third drain portion to an upper surface of the third source portion along a first side surface of the second spacer, and
wherein the gate electrode further includes a third gate portion overlapping a third channel area of the third active layer.

11. The display device of claim 10, further comprising:
an auxiliary source electrode spaced apart from the drain electrode; and
a connection electrode along a second side surface of the second spacer and electrically connecting the source electrode on the second spacer to the auxiliary source electrode.

12. The display device of claim 11, wherein the auxiliary source electrode is in the first metal layer in which the drain electrode is disposed, and the connection electrode is in the third metal layer in which the gate electrode is disposed.

13. The display device of claim 1, wherein the drain electrode further includes a third drain portion and a fourth drain portion,
wherein the source electrode further includes a third source portion and a fourth source portion,
wherein the first transistor further includes:
a second spacer disposed on the substrate and spaced apart from the first spacer;
a third active layer extending from an upper surface of the third drain portion to an upper surface of the third source portion along a first side surface of the second spacer; and
a fourth active layer extending from an upper surface of the fourth drain portion to an upper surface of the fourth source portion along a second side surface of the second spacer, and
wherein the gate electrode further includes a third gate portion overlapping a third channel area of the third active layer and a fourth gate portion overlapping a fourth channel area of the fourth active layer.

14. The display device of claim 13, further comprising a first capacitor on the first spacer, and a second capacitor on the second spacer,
wherein the first capacitor is between the gate electrode and the source electrode in a space where the first active layer and the second active layer are spaced apart,
wherein the second capacitor is between the gate electrode and the source electrode in a space where the third active layer and the fourth active layer are spaced apart, and
wherein the first capacitor and the second capacitor are connected in parallel.

15. The display device of claim 13, wherein the drain electrode further includes a fifth drain portion and a sixth drain portion,
wherein the source electrode further includes a fifth source portion and a sixth source portion,
wherein the first transistor further includes:
a third spacer on the substrate and spaced apart from the second spacer;
a fifth active layer extending from an upper surface of the fifth drain portion to an upper surface of the fifth source portion along a first side surface of the third spacer; and
a sixth active layer extending from an upper surface of the sixth drain portion to an upper surface of the sixth source portion along a second side surface of the third spacer, and
wherein the gate electrode further includes a fifth gate portion overlapping a fifth channel area of the fifth active layer and a sixth gate portion overlapping a sixth channel area of the sixth active layer.

16. The display device of claim 15, further comprising:
a first capacitor on the first spacer;
a second capacitor on the second spacer; and
a third capacitor on the third spacer,
wherein the first capacitor is between the gate electrode and the source electrode in a space where the first active layer and the second active layer are spaced apart,
wherein the second capacitor is between the gate electrode and the source electrode in a space where the third active layer and the fourth active layer are spaced apart, and
wherein the third capacitor is between the gate electrode and the source electrode in a space where the fifth active layer and the sixth active layer are spaced apart, and
wherein the first capacitor, the second capacitor, and the third capacitor are connected in parallel.

17. The display device of claim 4, wherein the first transistor is a vertical transistor, and the second transistor is a coplanar transistor.

18. A display device, comprising:
a substrate; and
a first transistor on the substrate, wherein the first transistor includes:
a drain electrode on the substrate;
an auxiliary source electrode on the substrate and spaced apart from the drain electrode;
a first spacer on the drain electrode and on the auxiliary source electrode;
a source electrode on an upper surface of the first spacer, the source electrode including a first source portion and a second source portion;
a first active layer extending from an upper surface of the drain electrode to an upper surface of the first source portion along a first side surface of the first spacer;
a connection electrode along a second side surface of the first spacer and electrically connecting the source electrode on the first spacer to the auxiliary source electrode;
a first gate insulation layer on the first active layer; and
a gate electrode on the first gate insulation layer and overlapping a first channel area of the first active layer.

19. The display device of claim 18, further comprising a second transistor on the substrate, wherein the second transistor includes:
an active layer on the substrate and including a channel area, a first connection area at one side of the channel area, and a second connection area at another side of the channel area;
a first electrode connected to the first connection area;
a second electrode connected to the second connection area;
a second gate insulation layer on the channel area; and
a third electrode on the second gate insulation layer and overlapping the channel area.

20. The display device of claim 19, further comprising:
a gate line on the substrate;
a subpixel on the substrate and connected to the gate line; and
a gate driving circuit on the substrate and outputting a gate signal having a turn-on level voltage or a turn-off level voltage to the gate line,
wherein the first transistor is included in the gate driving circuit, and
wherein the second transistor is included in the subpixel.

21. The display device of claim 19, further comprising:
a buffer layer between the substrate and the second transistor; and
a shield pattern between the substrate and the buffer layer, the shield pattern overlapping at least a portion of the second transistor,
wherein the first spacer includes a same insulating material as the buffer layer, and the first spacer has a thickness larger than a thickness of the buffer layer,
wherein the shield pattern is in a first metal layer, and
wherein the drain electrode and the auxiliary source electrode are in the first metal layer.
